(19) United States
(12) Patent Application Publication
(10) Pub. No.: US 2008/0026149 A1
(43) Pub. Date: Jan. 31, 2008

(54) METHODS AND SYSTEMS FOR SELECTIVELY DEPOSITING SI-CONTAINING FILMS USING CHLOROPOLYSILANES

(75) Inventors: Pierre Tomasini, Tempe, AZ (US); Chantal Arena, Mesa, AZ (US); Matthias Bauer, Phoenix, AZ (US); Nyles Cody, Tempe, AZ (US); Ronald Bertram, Gilbert, AZ (US); Jianqing Wen, Scottsdale, AZ (US); Matthew D. Stephens, Morristown, NJ (US)

Correspondence Address: KNOBBE, MARTENS, OLSEN & BEAR LLP, 2040 MAIN STREET, FOURTEENTH FLOOR, IRVINE, CA, 92614, US

(73) Assignee: ASM America, Inc., Phoenix, AZ (US)

(21) Appl. No.: 11/753,370

(22) Filed: May 24, 2007

Related U.S. Application Data
(60) Provisional application No. 60/809,745, filed on May 31, 2006.

(51) Int. Cl. C23C 16/00

(52) U.S. Cl. 427/255.28; 118/696; 118/728

(57) ABSTRACT

Chloropolysilanes are utilized in methods and systems for selectively depositing thin films useful for the fabrication of various devices such as microelectronic and/or microelectromechanical systems (MEMS).

This application claims priority to U.S. Provisional Patent Application Ser. No. 60/809,745, filed May 31, 2006, which is hereby incorporated by reference in its entirety.

### BACKGROUND OF THE INVENTION

1. Field of the Invention

This invention relates to systems and methods for using chlorinated disilanes and trisilanes to selectively deposit Si-containing films useful for the fabrication of various devices such as microelectronic and/or microelectromechanical systems (MEMS).

2. Description of the Related Art

A variety of methods are used in the semiconductor manufacturing industry to deposit materials onto surfaces. For example, one of the most widely used methods is chemical vapor deposition (“CVD”), in which atoms or molecules contained in a vapor deposit on a surface and build up to form a film. Deposition of silicon-containing (“Si-containing”) materials using conventional silicon sources and deposition methods, particularly non-epitaxial deposition, is believed to proceed in several distinct stages, see Peter Van Zant, “Microchip Fabrication,” 4^{th} Ed., McGraw Hill, New York, (2000), pp. 364-365. Nucleation, the first stage, is very important and is greatly affected by the nature and quality of the substrate surface. Nucleation occurs as the first few atoms or molecules deposit onto the surface and form nuclei. During the second stage, the isolated nuclei form small islands that grow into larger islands. In the third stage, the growing islands begin coalescing into a continuous film. At this point, the film typically has a thickness of a few tens of angstroms and is known as a “transition” film. It generally has chemical and physical properties that are different from the thicker bulk film that begins to grow after the transition film is formed.

While trisilane has long been known as a theoretical precursor for the deposition of silicon, few studies have been performed on it and few advantages have been recognized. Accordingly, significant commercial sources of trisilane have not developed historically. Recently, however, a variety of advantages for trisilane have been discovered. For example, U.S. Pat. No. 6,821,825, issued Nov. 23, 2004, discloses superior film uniformity deposited from trisilane. U.S. Pat. No. 6,900,115, issued May 31, 2005, similarly discloses uniformity and throughput benefits from use of trisilane when simultaneously depositing over mixed semiconductor and insulating surfaces.

As disclosed in U.S. Pat. No. 6,900,115, it is often desirable to achieve uniform deposition over both insulating (e.g., silicon oxide) and semiconductor (e.g., silicon) surfaces. On the other hand, in other situations it is desirable to deposit selectively within semiconductor windows exposed within fields of different materials, such as field isolation oxide (e.g., shallow trench isolation or STI). For example, heterojunction bipolar transistors are often fabricated using selective deposition techniques that deposit epitaxial single crystal semiconductor films only on active areas. Other transistor designs benefit from elevated source/drain structures, which provide additional silicon that can be consumed by the source/drain contact process without altering shallow junction device performance. Selective epitaxy on source/drain regions advantageously reduces the need for subsequent patterning and etch steps.

Generally speaking, selectivity takes advantage of differential nucleation during deposition on disparate materials. Selective deposition can generally be explained by simultaneous etching and deposition of the material being deposited. The precursor of choice will generally have a tendency to nucleate and grow more rapidly on one surface and less rapidly on another surface. For example, silane will generally nucleate on both silicon oxide and silicon, but there is a longer nucleation stage on silicon oxide. At the beginning of a nucleation stage, discontinuous films on oxide have a high exposed surface area relative to merged, continuous films on silicon. Accordingly, an etchant added to the process will have a greater effect upon the poorly nucleating film on oxide as compared to the rapidly nucleating film on silicon. The relative selectivity of a process can thus be tuned by adjusting factors that affect the deposition rate (e.g., precursor flow rates, temperature, pressure) and the rate of etching (e.g., etchant flow rate, temperature, pressure). Changes in each variable will generally have different effects upon etch rate and deposition rate. Typically, a commercial selective deposition process is tuned to produce the highest deposition rate feasible on the window of interest while accomplishing no deposition in the field regions. Known selective silicon deposition processes include reactants silane (silicon precursor) and hydrochloric acid (etchant) with a hydrogen carrier gas. U.S. Patent Publication No. 2005/0079692 A1 discloses the use of silane and hydrogen chloride to selectively deposit a Si film on a SiGe film, and lists various other silicon precursors and etchants. U.S. application Ser. No. 11/343,264, filed Jan. 30, 2006, which is hereby incorporated by reference in its entirety, discloses methods of selectively depositing Si-containing materials using trisilane and chlorine gas.

Chlorinated silanes, particularly dichlorosilane and trichlorosilane, have long been used as precursors for the deposition of epitaxial silicon. It has been theorized that the deposition mechanism involves the formation of various transient chlorinated polysilanes, see M. T. Swihart and R. W. Carr, “Thermochemistry and Thermal Decomposition of the Chlorinated Disilanes (Si₂HₙCl₆₋ₙ, n=0−6) Studied by ab Initio Molecular Orbital Methods,” J. Chem. Phys. A 1997, 101, 7434-7445, and M. T. Swihart and R. W. Carr, “On the Mechanism of Homogenous Decomposition of the Chlorinated Silanes. Chain Reactions Propagated by Divalent Silicon Species”, J. Phys. Chem. A 1998, 102, 1542-1549.

U.S. Patent Publication No. 2004/0224089 A1 discloses a number of chlorinated polysilanes. Theoretical experiments using trichlorodisilane and dichlorodisilane in the presence of a hydrogen carrier gas are disclosed. The deposition processes are said to liberate ligands (hydrogen and/or halogen) that are in situ etchants. Theoretical experiments using hydrogen chloride as a supplemental etchant in trichlorodisilane and dichlorodisilane deposition processes are also disclosed.

While various deposition processes are known in the art, continued scaling in pursuit of faster, less power-hungry circuitry has increased the demands on integrated circuit fabrication. Accordingly, deposition processes with improved uniformity, purity and repeatability are desired.

### SUMMARY OF THE INVENTION

Deposition processes have now been discovered that utilize chloropolysilanes as Si precursors. In embodiments, these depositions are less sensitive to nucleation phenomena compared to disilane or trisilane, and thus are particularly well-suited for providing selectivity to the deposition process. The processes work well with additive process gases, including carbon, germanium and/or dopant sources, and thus are useful for making various Si-containing films and for incorporating strain into the deposited layer or adjacent structures. In embodiments, the deposition processes employ a chlorine gas in combination with selected chloropolysilanes, particularly monochlorodisilane, dichlorodisilane, trichlorodisilane, and/or tetrachlorodisilane. Other embodiments provide systems useful for employing the chloropolysilanes to selectively deposit Si-containing films.

An embodiment provides a method of selectively depositing a Si-containing film, comprising:
establishing a selective chemical vapor deposition (CVD) condition in a CVD chamber, wherein establishing the selective CVD condition comprises flowing a chloropolysilane from a container to the CVD chamber and flowing a chlorine gas to the CVD chamber, the chloropolysilane comprising at least one of monochlorodisilane, dichlorodisilane, trichlorodisilane, and tetrachlorodisilane; and
selectively depositing a Si-containing film onto a single crystal surface region of a substrate disposed within the CVD chamber under the selective CVD condition while minimizing deposition onto a non-single crystalline surface region of the substrate during the selective deposition.

Another embodiment provides a deposition system, comprising:

a chemical vapor deposition (CVD) chamber configured to hold a substrate therein;

a chloropolysilane, wherein the chloropolysilane comprises at least one of monochlorodisilane, dichlorodisilane, trichlorodisilane, and tetrachlorodisilane;

a chlorine gas;

a first container holding the chloropolysilane, the first container being operatively connected to supply the chloropolysilane to the CVD chamber under a selective CVD condition, wherein the chloropolysilane comprises at least one of monochlorodisilane, dichlorodisilane, trichlorodisilane, and tetrachlorodisilane; and

a second container holding the chlorine gas, the second container being operatively connected to supply the chlorine gas to the CVD chamber under the selective CVD condition.

These and other embodiments are described in greater detail below.

### BRIEF DESCRIPTION OF THE DRAWINGS

These and other aspects of the invention will be readily apparent from the following description and from the appended drawings (not to scale), which are meant to illustrate and not to limit the invention, and in which:

FIG. 1 is a schematic cross section of a semiconductor substrate after field oxide definition, leaving insulator and semiconductor surfaces exposed.

FIG. 2 shows the structure of FIG. 1 after formation of a transistor gate electrode within an active area window.

FIG. 3 shows the structure of FIG. 2 after recessing source and drain regions on either side of the gate electrode.

FIG. 4 shows the structure of FIG. 3 after selective deposition of a semiconductor film within the recessed regions, in accordance with a preferred embodiment of the invention.

FIG. 5 shows the structure of FIG. 4 after optional continued selective deposition, forming elevated source/drain structures.

FIG. 6 shows the structures of FIG. 2 after exposing the semiconductor window and conducting a selective deposition to form elevated source/drain structures, in accordance with another preferred embodiment of the present invention.

FIGS. 7A-C show a series of schematic cross sections of a semiconductor substrate and illustrate a method of forming source/drain regions by blanket deposition and etching.

FIG. 8 shows two graphs illustrating the thermodynamic equilibria of various reactants as a function of temperature for a system including various chlorinated silicon species, with and without the addition of hydrogen carrier gas.

FIG. 9 is a schematic view of a reactor set up for a system employing a chloropolysilane and an inert, non-hydrogen carrier gas for depositing silicon-containing films in accordance with a preferred embodiment of the invention.

### DETAILED DESCRIPTION OF THE PREFERRED EMBODIMENTS

The term “polysilane” is used herein to refer to a silane that contains two or more silicon atoms, e.g., SiₙH₂ₙ₊₂, where n is 2 or greater, preferably 2 or 3, including mixtures thereof. Non-limiting examples of polysilanes include disilane and trisilane. The term “chloropolysilane” is used herein to refer to a chlorinated polysilane that contains one or more chlorine atoms and two or more silicon atoms. Non-limiting examples of chloropolysilanes include monochlorodisilane, dichlorodisilane, trichlorodisilane, tetrachlorodisilane, pentachlorodisilane, hexachlorodisilane, monochlorotrisilane, dichlorotrisilane, trichlorotrisilane, tetrachlorotrisilane, pentachlorotrisilane, hexachlorotrisilane, heptachlorotrisilane, octachlorotrisilane, and mixtures thereof. Polysilanes and chloropolysilanes can be obtained commercially and/or prepared by methods known to those skilled in the art. Chloropolysilanes containing two silicon atoms may be referred to herein as chlorinated disilanes, and chloropolysilanes containing three silicon atoms may be referred to herein as chlorinated trisilanes.

It will be understood by those skilled in the art that certain chloropolysilanes exist in various isomeric forms. Thus, reference herein to a chloropolysilane will be understood to encompass the corresponding isomeric forms unless stated otherwise. For example, it will be understood that 1,1-dichlorodisilane and 1,2-dichlorodisilane are isomeric forms of dichlorodisilane. Non-limiting examples of chloropolysilanes and their CAS registry numbers are provided in TABLE 1.

TABLE 1

| Chloropolysilane | CAS Registry No. |
|---|---|
| Monochlorodisilane | 14565-98-1 |
| Dichlorodisilane | 101673-04-5 |
| 1,2-Dichlorodisilane | 20536-13-4 |
| 1,1-Dichlorodisilane | 20424-84-4 |
| Trichlorodisilane | 99801-94-2 |
| 1,1,2-Trichlorodisilane | 20424-85-5 |
| 1,1,1-Trichlorodisilane | 78228-96-3 |
| Tetrachlorodisilane | 99995-72-9 |
| 1,1,1,2-Tetrachlorodisilane | 31411-97-9 |
| 1,1,2,2-Tetrachlorodisilane | 20536-16-7 |
| Pentachlorodisilane | 31411-98-0 |
| Hexachlorodisilane | 13465-77-5 |
| 1-Chlorotrisilane | 31411-99-1 |
| 2-Chlorotrisilane | 21509-73-9 |
| Dichlorotrisilane | 110608-89-4 |
| 1,2-Dichlorotrisilane | 93974-19-7 |
| 1,3-Dichlorotrisilane | 34118-70-2 |
| 1,2,3-Trichlorotrisilane | 102581-31-7 |
| 1,1,1-Trichlorotrisilane | 34551-78-5 |
| 1,1,3,3-Tetrachlorotrisilane | 34551-79-6 |
| 1,1,2,3,3-Pentachlorotrisilane | 192330-74-8 |
| 1,1,1,2,2,3-Hexachlorotrisilane | 192330-75-9 |
| 1,1,2,2,3,3-Hexachlorotrisilane | 89504-81-4 |
| 1,1,1,3,3,3-Hexachlorotrisilane | 62218-00-2 |
| 1,1,1,2,3,3,3-Heptachlorotrisilane | 62218-01-3 |
| 1,1,1,2,2,3,3-Heptachlorotrisilane | 56240-63-2 |
| Octachlorotrisilane | 13596-23-1 |

Various embodiments described herein provide methods of depositing Si-containing films. In general terms, these methods comprise establishing a chemical vapor deposition condition in a CVD chamber and depositing a Si-containing film onto a substrate disposed within the CVD chamber under the chemical vapor deposition condition. In various particular embodiments, the deposition is selective, e.g., the Si-containing film is selectively deposited onto a single crystal surface region of the substrate disposed within the CVD chamber under the selective CVD condition while minimizing deposition onto a non-single crystalline surface region of the substrate during the selective deposition. In an embodiment, the selective CVD condition comprises flowing a chloropolysilane and a chlorine gas from respective containers to the CVD chamber. It has been found that the use of chlorine gas in combination with a chloropolysilane is surprisingly effective for the selective deposition of Si-containing films, particularly in combination with preferred deposition temperatures in the range of about 400° C. to about 580° C. In preferred embodiments, the chloropolysilane comprises at least one of monochlorodisilane, dichlorodisilane, trichlorodisilane, and tetrachlorodisilane.

As used herein, the term “Si-containing” refers to a broad range of materials that contain Si, including SiGe, Si:C, SiGe:C, and doped versions thereof. The terms “SiGe”, “Si:C”, “SiGe:C” and similar terms refer to materials that contain the indicated elements (and, optionally, other ingredients) in various proportions. For example, “SiGe:C” is a material that comprises silicon, germanium, carbon and, optionally, other elements, e.g., dopants. The terms “SiGe”, “Si:C”, “SiGe:C” are not chemical stoichiometric formulas per se and thus are not limited to materials that contain particular ratios of the indicated elements. The percentage of a dopant (such as carbon, germanium or electrically active dopant) in a Si-containing film is expressed herein in atomic percent on a whole film basis, unless otherwise stated.

Chloropolysilanes useful in the deposition methods described herein include those mentioned above, each individually or in any combination thereof. Under the CVD conditions taught herein, the delivery of a chloropolysilane to the surface of a substrate (e.g., by flowing from a container to a CVD chamber having the substrate disposed therein) results in the deposition of a Si-containing film on the substrate. “Substrate,” as employed herein, refers either to the workpiece upon which deposition is desired, or the surface exposed to the deposition gases. For example, the substrate may be a single crystal silicon wafer, or may be a semiconductor-on-insulator (SOI) substrate, or may be an epitaxial Si, SiGe or Group III-V material deposited upon such wafers. Workpieces are not limited to wafers, but also include glass, plastic, or any other substrate employed in semiconductor processing. As is well known, semiconductor processing is most commonly employed for the fabrication of integrated circuits, which entails particularly stringent quality demands, but such processing is also employed in a variety of other fields. For example, semiconductor processing techniques are often employed in the fabrication of flat panel displays using a wide variety of technologies and in the fabrication of microelectromechanical systems (MEMS).

The term “mixed substrate” is known to those skilled in the art, see U.S. Pat. No. 6,900,115 (issued May 31, 2005), entitled “Deposition Over Mixed Substrates,” which is hereby incorporated herein by reference in its entirety and particularly for the purpose of describing mixed substrates. As discussed in U.S. Pat. No. 6,900,115, a mixed substrate is a substrate that has two or more different types of surfaces. In certain embodiments, Si-containing layers are selectively deposited on the exposed surfaces of single crystal semiconductor materials while minimizing and more preferably avoiding deposition on adjacent dielectrics. Examples of dielectric materials include silicon dioxide (including low dielectric constant forms such as carbon-doped or fluorine-doped), silicon nitride, metal oxide and metal silicate. There are various ways that the surfaces of a mixed substrate can be different from each other. For example, the surfaces can be made from different elements such as copper or silicon, or from different metals, such as copper or aluminum, or from different Si-containing materials, such as silicon or silicon dioxide. The electrical properties of surfaces can also make them different from each other.

Even if the materials are made from the same element, the surfaces can be different if the morphologies (crystallinity) of the exposed surfaces are different. The processes described herein are useful for depositing Si-containing films on a variety of substrates, but are particularly useful for deposition onto mixed substrates having mixed surface morphologies. Such a mixed substrate comprises a first exposed surface having a first surface morphology and a second exposed surface having a second surface morphology. In this context, “surface morphology” refers to the crystalline structure of the substrate surface. Amorphous and crystalline are examples of different morphologies. Polycrystalline morphology is a crystalline structure that consists of a disorderly arrangement of orderly crystals and thus has an intermediate degree of order. The atoms in a polycrystalline material are ordered within each of the crystals, but the crystals themselves lack long range order with respect to one another. Single crystal morphology is a crystalline structure that has a high degree of long range order. Epitaxial films are characterized by a crystal structure and orientation that is identical to the substrate upon which they are grown, typically single crystal. The atoms in these materials are arranged in a lattice-like structure that persists over relatively long distances (on an atomic scale). Amorphous morphology is a non-crystalline structure having a low degree of order because the atoms lack a definite periodic arrangement. Other morphologies include microcrystalline and mixtures of amorphous and crystalline material. As used herein, “single-crystal” or “epitaxial” is used to describe a predominantly large crystal structure that may have a tolerable number of faults therein, as is commonly employed for transistor fabrication. The skilled artisan will appreciate that crystallinity of a layer generally falls along a continuum from amorphous to polycrystalline to single-crystal; the skilled artisan can readily determine when a crystal structure can be considered single-crystal or epitaxial, despite low density faults. Specific examples of mixed substrates include without limitation single crystal/polycrystalline, single crystal/amorphous, epitaxial/polycrystalline, epitaxial/amorphous, single crystal/dielectric, epitaxial/dielectric, conductor/dielectric, and semiconductor/dielectric. The term “mixed substrate” includes substrates having more than two different types of surfaces, and thus the skilled artisan will understand that methods described herein for depositing Si-containing films onto mixed substrates having two types of surfaces may also be applied to mixed substrates having three or more different types of surfaces.

Various embodiments provide methods for selective deposition onto a mixed substrate, e.g., for depositing the Si-containing film onto one or more selected (typically single crystal) exposed surface region(s) of the mixed substrate while minimizing and preferably avoiding deposition onto other (typically non-single crystalline) exposed surface region(s) of the substrate during the selective deposition. In an embodiment, the Si-containing film is epitaxially or heteroepitaxially deposited onto the mixed substrate. The terms “epitaxial”, “epitaxially” “heteroepitaxial”, “heteroepitaxially” and similar terms are used herein to refer to the deposition of a crystalline Si-containing material onto a crystalline substrate in such a way that the deposited layer adopts or follows the lattice constant of the substrate. Epitaxial deposition is considered to be heteroepitaxial when the composition of the deposited layer is different from that of the substrate. In a preferred embodiment, the epitaxial or heteroepitaxial deposition is selective.

An embodiment provides a method of selectively depositing a Si-containing film, comprising: establishing a selective chemical vapor deposition (CVD) condition in a CVD chamber, wherein establishing the selective CVD condition comprises flowing a chloropolysilane from a container to the CVD chamber and flowing a chlorine gas to the CVD chamber, the chloropolysilane comprising at least one of monochlorodisilane, dichlorodisilane, trichlorodisilane, and tetrachlorodisilane; and selectively depositing a Si-containing film onto a single crystal surface region of a substrate disposed within the CVD chamber under the selective CVD condition while minimizing deposition onto a non-single crystalline surface region of the substrate during the selective deposition. Surprisingly, it has been found that CVD under a selective deposition condition as described herein is significantly enhanced by utilizing a combination of chlorine and at least one of monochlorodisilane, dichlorodisilane, trichlorodisilane, and tetrachlorodisilane.

This invention is not bound by theory, but it is believed that the surprising effectiveness of chlorine in combination with monochlorodisilane, dichlorodisilane, trichlorodisilane, and/or tetrachlorodisilane may be due at least in part to the tendency of these chloropolysilanes to form reactive intermediates comprising at least two of :SiHCl, :SiH₂ and :SiCl₂ under the selective CVD conditions described herein. The following chemical equations illustrate possible reaction pathways for the generation of various products under a selective CVD condition for each of monochlorodisilane, dichlorodisilane, trichlorodisilane, and tetrachlorodisilane:

Monochlorodisilane
H₂ClSiSiH₃(g)→H₂ClSiSiH:(g)+H₂(g) (1a)
H₂ClSiSiH:(g) [symbol] HClSi=SiH₂(g) (2a)
HClSi=SiH₂(g) [symbol] :SiHCl(g)+:SiH₂(g) (3a)
Si₂H₅Cl(g)→:SiH₂(g)+SiClH₃(g) (4a)
Si₂H₅Cl(g)→:SiHCl(g)+SiH₄(g) (5a)
Si₂H₅Cl(g)+Cl₂(g)→Si₂H₄Cl₂(g)+HCl(g) (6a)

Dichlorodisilane
HCl₂SiSiH₃(g)→HCl₂SiSiH:(g)+H₂(g) (1b)
H₂ClSiSiH₂Cl(g)→H₂ClSiSiCl:(g)+H₂(g) (2b)
HCl₂SiSiH:(g) [symbol] Cl₂Si=SiH₂(g) (3b)
Cl₂Si=SiH₂(g) [symbol] :SiCl₂(g)⁺:SiH₂(g) (4b)
Si₂H₄Cl₂(g)→:SiH₂(g)+SiCl₂H₂(g) (5b)
Si₂H₄Cl₂(g)→:SiHCl(g)+SiClH₃(g) (6b)
Si₂H₄Cl₂(g)→:SiCl₂(g)+SiH₄(g) (7b)
1,1Si₂H₄Cl₂(g)+Cl₂(g)→1,1,2Si₂H₃Cl₃(g)+HCl(g) (8b)

Trichlorodisilane
Cl₃SiSiH₃(g)→Cl₃SiSiH:(g)+H₂(g) (1c)
HCl₂SiSiClH₂(g)→HCl₂SiSiCl:(g)+H₂(g) (2c)
Cl₃SiSiH:(g) [symbol] Cl₂Si=SiHCl(g) (3c)
HCl₂SiSiCl:(g) [symbol] Cl₂Si=SiHCl(g) (4c)
Cl₂Si=SiHCl(g) [symbol] :SiCl₂(g)+:SiHCl(g) (5c)
Si₂H₃Cl₃(g)→:SiH₂(g)+SiCl₃H(g) (6c)
Si₂H₃Cl₃(g)→:SiHCl(g)+SiCl₂H₂(g) (7c)
Si₂H₃Cl₃(g)→:SiCl₂(g)+SiClH₃(g) (8c)
Si₂H₃Cl₃(g)+Cl₂(g)Si₂H₂Cl₄(g)+HCl(g) (9c)

Tetrachlorodisilane
Cl₃SiSiClH₂(g)→Cl₃SiSiCl:(g)+H₂(g) (1d)
HCl₂SiSiCl₂H(g)→Cl₃SiSiCl:(g)+H₂(g) (2d)
Cl₃SiSiCl:(g) [symbol] Cl₂Si=SiCl₂(g) (3d)
Cl₂Si=SiCl₂(g) [symbol] 2:SiCl₂(g) (4d)
Si₂H₂Cl₄(g)→:SiH₂(g)+SiCl₄(g) (5d)
Si₂H₂Cl₄(g)→:SiHCl(g)+SiCl₃H(g) (6d)
Si₂H₂Cl₄(g)→:SiCl₂(g)+SiCl₂H₂(g) (7d)
Si₂H₂Cl₄(g)+Cl₂(g)→Si₂HCl₅(g)+HCl(g) (8d)

Chemical equations (3a), (4a), (5a), (4b), 5(b), (6b), (7b), (5c), (6c), (7c), (8c), (4d), (5d), (6d), and (7d) illustrate reaction pathways that appear to contribute to the formation of the reactive intermediates :SiHCl, :SiH₂ and/or :SiCl₂. In turn, these reactive intermediates appear to contribute significantly to silicon deposition in accordance with the reaction pathways illustrated by chemical equations 1(e), 2(e) and (3e) below.

Chlorine both enhances silicon deposition (apparently by reacting with :SiH₂ as illustrated by equation (3e)), and enhances deposition selectivity (apparently by removing portions of the deposited silicon as illustrated by chemical equation (1f) below). It will be understood that the various reaction pathways and chemical equations discussed herein are illustrative and not exhaustive. For example, various additional reaction pathways that may be operative under a given CVD condition are illustrated by equations (1g) to (16g) below. It will be appreciated that some of the reaction pathways pertain to particular CVD conditions that may not be present in all situations. For example, equations (4g) and 5(g) illustrate the use of phosphine (PH₃), an electrically active dopant precursor, as described in greater detail below.

Deposition
:SiCl₂(g)+H₂(g)→Si(s)+2HCl(g) (1e)
:SiHCl(g)→Si(s)+HCl(g) (2e)
:SiH₂(g)+Cl₂(g)→Si(s)+2HCl(g) (3e)

Etching by Chlorine
Si(s)+Cl₂(g)→:SiCl₂(g) (1f)

Additional Reaction Pathways
Si(s)+2HCl [symbol] SiCl₂(g)+H₂(g) (1g)
:SiCl₂(g)+2H(a)→Si(s)+2HCl(g) (2g)
:SiH₂(g)+2Cl(a)→Si(s)+2HCl(g) (3g)
PH₃(g)+6Cl(a)→PCl₃(g)+3HCl(g) (4g)
2PH₃(g)→2P(s)+3H₂(g) (5g)
Cl₂(g)+H₂(g)→2HCl(g) (6g)
H(s)+Cl(a)→HCl(g) (7g)
2H(a)→H₂(g) (8g)
2SiCl(a)→SiCl₂(a)→SiCl₂(g) (9g)
SiH₄(g)+Cl₂(g)→SiH₃Cl(g)+HCl(g) (10g)
SiH₃Cl(g)+Cl₂(g)→SiH₂Cl₂(g)+HCl(g) (11g)
SiH₂Cl₂(g)+Cl₂(g)→SiHCl₃(g)+HCl(g) (12g)
SiHCl₃(g)+Cl₂(g)→SiCl₄(g)+HCl(g) (13g)
:SiH₂(g)+Cl₂(g)→SiH₂Cl₂(g) (14g)
:SiHCl(g)+Cl₂(g)→SiHCl₃(g) (15g)
:SiCl₂(g)+Cl₂(g)→SiCl₄(g) (16g)

In various embodiments, a selective CVD condition comprising the use of chlorine in combination with monochlorodisilane, dichlorodisilane, trichlorodisilane and/or tetrachlorodisilane provides significant benefits. For example, those skilled in the art will appreciate that, under a selective CVD condition as described herein, one or more of the reactive intermediates :SiHCl, :SiH₂ and :SiCl₂ are generated from monochlorodisilane, dichlorodisilane, trichlorodisilane and tetrachlorodisilane in accordance with equations (3a), (4a), (5a), (4b), 5(b), (6b), (7b), (5c), (6c), (7c), (8c), (4d), (5d), (6d), and (7d). These reactive intermediates result in the deposition of silicon in accordance with equations (1e), (2e) and (3e). Advantageously, it has been found that such depositions may be carried out at relatively low temperatures. Thus, in an embodiment, the selective CVD condition comprises a temperature (e.g., a CVD chamber and/or substrate temperature) in the range of about 400° C. to about 590° C., preferably in the range of about 500° C. to about 580° C. Preferred selective CVD conditions comprise various combinations of chlorine use, preferred chloropolysilane use, and preferred deposition temperatures.

The use of chlorine in combination with these chloropolysilanes advantageously produces additional chloropolysilanes in accordance with equations (6a), (8b), (9c), and (8d); produces deposited silicon in accordance with equation (3e); and produces etching in accordance with equations (1f). Although hydrogen chloride (HCl) may be present, the use of hydrogen chloride as an additional etchant is preferably minimized. Surprisingly, the presence of significant quantities of hydrogen chloride, such as those traditionally used for etching, may be detrimental. This invention is not bound by theory, but it is believed that the presence of HCl inhibits deposition by slowing the forward reaction pathways illustrated by equations (1e), (2e) and (3e) and that HCl use does not advantageously produce additional chloropolysilanes. Etching by HCl, as illustrated by equation (1g), is relatively slow at low temperatures, and thus selectivity may be undesirably low for HCl at deposition temperatures in the range of about 400° C. to about 590° C. Thus, in an embodiment, the selective CVD condition comprises minimizing flowing hydrogen chloride to the CVD chamber. In a preferred embodiment, the selective CVD condition comprises substantially no flowing hydrogen chloride to the CVD chamber.

Deposition may be suitably conducted according to the various CVD methods known to those skilled in the art, but the greatest benefits are obtained when deposition is conducted under the CVD deposition conditions taught herein. The disclosed methods may be suitably practiced by employing CVD, including plasma-enhanced chemical vapor deposition (PECVD) or thermal CVD, utilizing a chloropolysilane to deposit a Si-containing film onto a substrate within a CVD chamber, preferably in combination with a chlorine flow to selectively deposit a Si-containing film onto a single crystal surface region of a substrate disposed within the CVD chamber under the selective CVD condition while minimizing deposition onto a non-single crystalline surface region of the substrate during the selective deposition. For example, the CVD conditions may be chosen to selectively deposit an epitaxial Si-containing film onto one or more exposed windows of a mixed substrate. Preferably, minimizing deposition onto the non-single crystalline surface region comprises depositing substantially no Si-containing material onto the non-single crystalline surface region during the selective deposition. Thermal CVD is preferred, as selective deposition can be achieved effectively without the risk of damage to substrates and equipment that attends plasma processing.

In an embodiment, delivery of the chloropolysilane to the substrate surface is accomplished by flowing the chloropolysilane from a container to a suitable CVD chamber having the substrate disposed therein. The chloropolysilane is preferably introduced to the chamber in the form of a gas or as a component of a feed gas. In an embodiment, the chloropolysilane is introduced to the CVD chamber by flowing it from a container that holds the chloropolysilane into the CVD chamber through a suitable supply line(s), preferably equipped with one or more valves to control the flow rate and/or pressure. The chloropolysilane may be held in the container in a liquid or gaseous form, preferably as a liquid. In an embodiment, the chloropolysilane is pressurized within the container. Such a pressurized chloropolysilane may be caused to flow into the chamber by creating a pressure differential between the supply line and the pressurized chloropolysilane, e.g., by reducing the pressure within the supply line to below the pressure in the container. In an embodiment, the container comprises a bubbler, and the liquid chloropolysilane is caused to flow into a chamber by bubbling a carrier gas through the chloropolysilane to entrain chloropolysilane vapor and carry it through the supply line to the chamber. In an embodiment, the bubbler is a temperature controlled bubbler. Preferably, the container is equipped with a delivery system comprising a bubbler and a gas concentration sensor that measures the amount of chloropolysilane in the carrier gas flowing from the bubbler. Such sensors are commercially available, e.g., Piezocon® gas concentration sensors from Lorex Industries, Poughkeepsie, N.Y., U.S.A. In addition to the chloropolysilane, the feed gas may comprise other components in gaseous or vaporous form, e.g., a carrier gas, a second silicon source, a carbon source, a germanium source, a nitrogen source, a dopant source, etchant(s) (e.g., chlorine gas for selective deposition embodiments), etc. In a preferred embodiment, the chloropolysilane comprising at least one of monochlorodisilane, dichlorodisilane, trichlorodisilane, and tetrachlorodisilane, and a selective CVD condition is chosen that comprises flowing both chlorine gas and the chloropolysilane to the CVD chamber.

A suitable manifold may be used to supply feed gas(es) to the CVD chamber. In an embodiment, the gas flow in the CVD chamber is horizontal. Preferably, the CVD chamber is included in single wafer reactor. More preferably, the chamber is a single-wafer, single pass, laminar horizontal gas flow reactor, preferably radiantly heated. Suitable reactors of this type are commercially available, and preferred models include the Epsilon™ series of single wafer reactors commercially available from ASM America, Inc. of Phoenix, Ariz. While the methods described herein can also be employed in alternative reactors, such as a showerhead arrangement, benefits in increased uniformity and deposition rates have been found particularly effective in the horizontal, single-pass laminar gas flow arrangement of the Epsilon™ chambers, employing a rotating substrate, particularly with low process gas residence times. CVD may be conducted by introducing plasma products (in situ or downstream of a remote plasma generator) to the chamber, but as noted above, thermal CVD is preferred.

Upon delivery of the chloropolysilane to the substrate surface, deposition is preferably conducted under the CVD conditions (e.g., deposition pressure, deposition temperature and reactant flow conditions) taught herein, in light of the properties of the chosen chloropolysilane. The total pressure in the CVD chamber is preferably in the range of about 0.001 Torr to about 1000 Torr, more preferably in the range of about 0.1 Torr to about 350 Torr, most preferably in the range of about 0.25 Torr to about 100 Torr. In an embodiment, the selective CVD condition comprises a CVD chamber pressure in the range of about 20 Torr to about 760 Torr. The partial pressure of chloropolysilane in the chamber is preferably in the range of about 0.0001% to about 100% of the total pressure, more preferably about 0.001% to about 5% of the total pressure. As noted above, the feed gas can also include a gas or gases other than chloropolysilane, such as other silicon sources, germanium source(s), carbon source(s), etchant(s) (e.g., chlorine gas for selective deposition embodiments), dopant precursor(s) and/or inert carrier gases. In an embodiment, the chloropolysilane is the sole source of silicon. He, Ar, H₂, N₂ are possible carrier gases for the methods described herein. In some embodiments, non-hydrogen carrier gases such as He, Ar and N₂ are preferred, as described in greater detail below.

In an embodiment, the chloropolysilane is introduced to the chamber along with a carrier gas, using a relatively high chloropolysilane flow rate and a relatively low carrier gas flow rate, as compared to standard use of silane or silane/hydrogen chloride in place of chloropolysilane. For example, in a preferred embodiment thermal CVD is carried out in an Epsilon E2500™, E3000™ or E3200™ reactor system (available commercially from ASM America, Inc., of Phoenix, Ariz.) using a chloropolysilane flow rate of about 5 mg/min to 500 mg/min, more preferably between about 70 mg/min and 300 mg/min. The carrier gas flow rate may be about 40 standard liters per minute (slm) or less, preferably about 10 slm or less, more preferably about 5 slm or less, and the deposition temperature may be in the range of about 400° C. to about 800° C., more preferably about 500° C. to about 700° C. Selective CVD conditions preferably comprise a substrate temperature that is greater than about 400° C. and less than 600° C. Flowing hydrogen gas is preferably minimized during deposition. For selective depositions, etchant gas (e.g., chlorine) may be used, at flow rates that are preferably 1-200 sccm. In some embodiments, the chlorine content of the chloropolysilane is sufficiently high that selective depositions may be conducted without an added etchant. Dopant precursor (e.g., carbon source and/or electrically active dopant precursor) flow rates are typically in the range of from about 10 sccm to about 1,000 sccm, depending on the nature of the dopant source and the relative flow rates of the other components. For example, for phosphorus doping, dopant hydride (precursor) flow rates are preferably from 10-200 sccm of phosphine (e.g., 1% PH₃ in H₂ or He).

Thermal CVD conditions preferably include a substrate temperature that is effective to deposit a Si-containing film of the desired morphology (e.g., amorphous, polycrystalline, single crystalline) over the substrate. Preferably, thermal CVD is conducted at a temperature in the range of about 350° C. to about 900° C., more preferably about 500° C. to about 800° C. PECVD is preferably conducted at a temperature in the range of about 300° C. to about 700° C. Those skilled in the art, informed by the guidance provided herein, can adjust these temperature ranges to take into account the realities of actual manufacturing, e.g., the properties of the chosen chloropolysilane, preservation of thermal budget, deposition rate, different sizes of chambers, including single wafer and batch reactors, preferred total pressures and partial pressures etc. In general, higher partial pressures entail lower temperatures for a given desired result, whether it be deposition rate, layer quality or a combination of the two. The substrate can be heated by a variety of methods known in the art, e.g., resistive heating and lamp heating. For selective depositions embodiments comprising the use of chlorine in combination with a chloropolysilane that comprises at least one of monochlorodisilane, dichlorodisilane, trichlorodisilane, and tetrachlorodisilane, the selective CVD condition preferably comprises a substrate temperature in the range of about 400° C. to about 580° C. In an embodiment, the selective CVD condition comprises a substrate temperature that is effective to epitaxially or heteroepitaxially deposit the Si-containing film onto a single crystal surface region of a mixed substrate, while minimizing deposition onto a non-single crystalline surface region of the substrate during the selective deposition.

Depositions, including selective depositions, can be carried out using at least two chloropolysilanes selected from monochlorodisilane (chlorodisilane), dichlorodisilane, trichlorodisilane, tetrachlorodisilane, pentachlorodisilane, hexachlorodisilane, chlorotrisilane, dichlorotrisilane, trichlorotrisilane, tetrachlorotrisilane, pentachlorotrisilane, hexachlorotrisilane, heptachlorotrisilane, and octachlorotrisilane. In some embodiments, the depositions can be carried out using at least three of the aforementioned chloropolysilanes. The two or more chloropolysilanes may be supplied to the CVD separately, e.g., from separate containers, or as components of a mixture. In an embodiment, the selective CVD condition comprises flowing a first chloropolysilane and a second chloropolysilane to the CVD chamber, where the first chloropolysilane comprises monochlorodisilane, dichlorodisilane, trichlorodisilane, or tetrachlorodisilane, and the second chloropolysilane is different from the first chloropolysilane. The weight ratio of the first chloropolysilane to the second chloropolysilane may vary over a broad range, e.g., in the range of about 99:1 to about 1:99, preferably in the range of about 9:1 to about 1:9, more preferably in the range of about 3:1 to about 1:3. For example, in an embodiment, the chloropolysilane is a mixture that comprises dichlorodisilane and trichlorodisilane, e.g., at a dichlorodisilane:trichlorodisilane weight ratio in the range of about 1:9 to about 9:1, preferably in the range of about 3:1 to 1:3. A preferred chloropolysilane embodiment consists essentially of about 75% by weight dichlorodisilane and 25% by weight trichlorodisilane. In another embodiment, the first and second chloropolysilanes are flowed to the CVD chamber from separate containers. In an embodiment, the selective CVD condition comprises flowing a first chloropolysilane, a second chloropolysilane and a third chloropolysilane to the CVD chamber, where the first chloropolysilane comprises monochlorodisilane, dichlorodisilane, trichlorodisilane, or tetrachlorodisilane, and where the second and third chloropolysilanes are different from each other and different from the first chloropolysilane. The relative amounts of the first, second and third chloropolysilanes may vary over a broad range, e.g., each may be used in a relative amount of from about 1% to about 98% by weight based on total chloropolysilane weight.

As mentioned above, in addition to chloropolysilane the feed gas may also contain other materials known by those skilled in the art to be useful for doping or alloying Si-containing films, as desired. In various embodiments, the feed gas(es) further comprises one or more precursors selected from the group consisting of silicon source, germanium source, carbon source, boron source, gallium source, indium source, arsenic source, phosphorous source, and antimony source. Specific examples of such sources include: silane, disilane and tetrasilane as supplemental silicon sources in addition to chloropolysilane; germane, monochlorogermane, dichlorogermane, trichlorogermane, tetrachlorogermane, digermane, chlorodigermane, dichlorodigermane, trichlorodigermane, tetrachlorodigermane, pentachlorodigermane, and hexachlorodigermane as germanium sources; monosilylmethane, disilylmethane, trisilylmethane, tetrasilylmethane, monomethyl silane (MMS) and dimethyl silane as sources of both carbon and silicon; and various dopant precursors as sources of electrically active dopants (both n-type and p-type) such as antimony, arsenic, boron, gallium, indium and phosphorous. In some embodiments, a carbon source comprises H₃Si—CH₂—SiH₂—CH₃(1,3-disilabutane).

Incorporation of dopants into Si-containing films by CVD using chloropolysilane is preferably accomplished by in situ doping using dopant precursors. Preferred precursors for electrical dopants are dopant hydrides, including p-type dopant precursors such as diborane, deuterated diborane, and n-type dopant precursors such as phosphine and arsine. Silylphosphines [(H₃Si)₃₋ₓPRₓ] and silylarsines [(H₃Si)₃₋ₓAsRₓ] where x=0−2 and Rₓ═H and/or D are alternative precursors for phosphorous and arsenic dopants. SbH₃ and trimethylindium are alternative sources of antimony and indium, respectively. Such dopant precursors are useful for the preparation of preferred films as described below, preferably boron-, phosphorous-, antimony-, indium-, and arsenic-doped silicon, Si:C, SiGe and SiGe:C films and alloys.

The amount of dopant precursor in the feed gas may be adjusted to provide the desired level of dopant in the Si-containing film and/or for the desired surface quality in the deposited layer Si-containing layer. Preferred concentrations in the feed gas are in the range of about 1 part per billion (ppb) to about 20% by weight based on the weight of total reactive gas (excluding inert carrier and diluent gases), preferably between about 0.1 sccm to 5 sccm of pure phosphine (or equivalent diluted phosphine) or arsine or diborane although higher or lower amounts are sometimes preferred in order to achieve the desired property in the resulting film. In the preferred Epsilon™ series of single wafer reactors, dilute mixtures of dopant precursor in a carrier gas can be delivered to the reactor via a mass flow controller with set points ranging from about 10 to about 1000 standard cubic centimeters per minute (sccm), depending on desired dopant concentration and dopant gas concentration. Dilution of dopant gases can lead to factors of 10⁻⁷ to 10⁻² to arrive at equivalent pure dopant flow rates. Typically commercially available dopant sources are dopant hydrides diluted in H₂. However, in some embodiments dopant precursors are diluted in non-hydrogen inert gas. The dilute mixture is preferably further diluted by mixing with chloropolysilane, optional etchant (for selective deposition embodiments), any suitable carrier gas, and any desired dopant precursor for substitutional doping (e.g., germane or monomethyl silane). Since typical total flow rates for deposition in the preferred Epsilon™ series reactors often range from about 10 standard liters per minute (slm) to about 100 slm, the concentration of the dopant precursor used in such a method is generally small relative to total flow.

Selective CVD Conditions

Deposition conditions generally suitable for selective CVD are described above and include ranges of values for parameters such as chloropolysilane type and flow rate, etchant type and flow rate, carrier gas identity and flow rate, equipment type and configuration, deposition temperature, deposition pressure, carrier gas identity and flow rate, etc. A selective CVD condition suitable for a particular deposition may be identified by routine experimentation informed by the guidance provided herein.

The term “selective deposition” as used herein refers to the deposition of Si-containing material on a single crystal surface of a mixed substrate (e.g., a substrate having both single crystal and non-single crystal surfaces, or semiconductor and insulating surfaces), with little or no deposition on the non-single crystal surface(s). Excellent selectivity can be obtained by using a feed gas that contains a chloropolysilane using the deposition methods described herein. In an embodiment, a Si-containing film is deposited onto a single crystal surface region of a substrate disposed within the CVD chamber under the selective CVD condition while minimizing deposition onto a non-single crystalline surface region of the substrate during the selective deposition. Preferably, minimizing deposition onto the non-single crystalline surface region comprises depositing substantially no Si-containing material onto the non-single crystalline surface region during the selective deposition. Thus, selectivity may be about 100%, e.g., deposition on the single crystal surfaces of mixed substrates with essentially zero deposition on surrounding insulators such as silicon oxide and silicon nitride. In preferred embodiments, the selectively deposited Si-containing material comprises epitaxial Si or heteroepitaxial SiGe, Si:C or SiGe:C, any of which may be doped with electrically active dopants.

In an embodiment, selectivity is obtained using a chloropolysilane, without the addition of an additional etchant species. Traditionally, an HCl etchant was provided to selective silicon-based deposition processes, where the etch effect upon slow-nucleating deposition on amorphous (typically insulating) surfaces was greater than the etch effects on exposed semiconductor surfaces. HCl, however, is notoriously difficult to purify and typical commercial sources of HCl introduce excessive moisture into the deposition process. Such moisture can lower the conductivity of deposited films, and cause unacceptable levels of defects in epitaxial deposition. Accordingly, in some embodiments the use of chloropolysilane advantageously achieves high levels of selectivity without added etchants, and particularly without HCl.

Chloropolysilanes having a relatively high chlorine:hydrogen ratio are preferred for achieving selectivity in the absence of etchants. For example, preferred chloropolysilanes for achieving selectivity have a chlorine:hydrogen molar ratio that is greater than about 1:3, e.g., in the range of from about 1:3 to about 7:1. Pentachlorodisilane is an example of a chloropolysilane having a chlorine:hydrogen molar ratio of 5:1. The chloropolysilane may comprise two or more individual chloropolysilanes. A desired chlorine:hydrogen molar ratio can be achieved by selecting appropriate amounts of particular individual chloropolysilanes for inclusion in such a mixture. For example, the chlorine:hydrogen molar ratio of a chloropolysilane that contains dichlorodisilane and tetrachlorodisilane may be controlled over a range of about 1:3 (essentially pure dichlorodisilane) to about 2:1 (essentially pure tetrachlorodisilane) by appropriate selection of the relative amounts of the two individual chloropolysilanes.

Although control over selectivity may be achieved by such selection of the chloropolysilane(s) in the absence of an added etchant, it has been found that the use of chlorine gas as an etchant is particularly advantageous, particularly in combination with chloropolysilanes having a relatively lower chlorine:hydrogen ratio such as monochlorodisilane, dichlorodisilane, trichlorodisilane, and/or tetrachlorodisilane, and more preferably in combination with preferred deposition temperatures, e.g., in the range of about 400° C. to less than 600° C. In an embodiment, the use of chlorine in combination with monochlorodisilane, dichlorodisilane, trichlorodisilane and/or tetrachlorodisilane provides significant benefits, including one or more of a relatively low deposition temperatures (e.g., a CVD chamber and/or substrate temperature in the range of about 400° C. to about 590° C., preferably in the range of about 500° C. to about 580° C.); a relatively high deposition rate (e.g., about 140 Å per minute or higher, preferably about 180 Å per minute or higher); and high selectivity. Use of chlorine allows for selectivity to be controlled by manipulating the chlorine flow rate rather than by manipulating the chlorine:hydrogen molar ratio of the chloropolysilane, which may be more desirable in some equipment configurations. The use of chlorine also allows hydrogen chloride use to be significantly minimized or, preferably, substantially eliminated, which may provide additional benefits as discussed above.

The following general trends are provided for the purpose of guiding routine experimentation conducted to identify CVD conditions suitable for a particular chloropolysilane deposition, and supplement guidance provided elsewhere herein.

As the chlorine content of the chloropolysilane increases, the degree of reactivity tends to decrease and the degree of selectivity tends to increase. Thus, to achieve a given deposition rate and degree of selectivity, relatively higher deposition temperatures are preferred as the chlorine content of the chloropolysilane increases. In an embodiment, a selective CVD condition comprises a substrate temperature in the range of about 400° C. to about 580° C. As deposition pressure increases, deposition rate tends to increase. In an embodiment, a selective CVD condition comprises a CVD chamber pressure in the range of about 20 Torr to about 760 Torr. Higher deposition temperatures tend to favor epitaxial or heteroepitaxial deposition, whereas lower temperatures tend to favor amorphous deposition. In an embodiment, the substrate temperature is effective to epitaxially or heteroepitaxially deposit the Si-containing film onto the single crystal surface region of the substrate. As the amount of chlorine gas used in combination with the chloropolysilane increases, selectivity tends to increase and deposition rate tends to decrease. The effect of chlorine flow rate on deposition rate and selectivity is illustrated in the Examples below.

In general, lower H₂ carrier gas flow rates improve selectivity in the chloropolysilane deposition process as discussed in greater detail below. As the etching mechanism competes with the deposition mechanism even over semiconductor windows, a number of variables can differentially affect the two mechanisms to modulate net growth rates (“GR”) over semiconductor surfaces. For example, under the test conditions in the EPSILON® chamber, increasing the chlorine:hydrogen ratio of the chloropolysilane generally reduces deposition rate.

Exemplary Process Integration

In an embodiment, a selective deposition using chlorine and a chloropolysilane as described herein is used to selectively form a silicon contact plug. For example, a relatively thick insulating layer, such as BPSG or TEOS, is patterned and contact vias are opened to expose a single-crystal semiconductor surface. The selective deposition is employed to grow an epitaxial or polysilicon plug from the surface up through the contact hole.

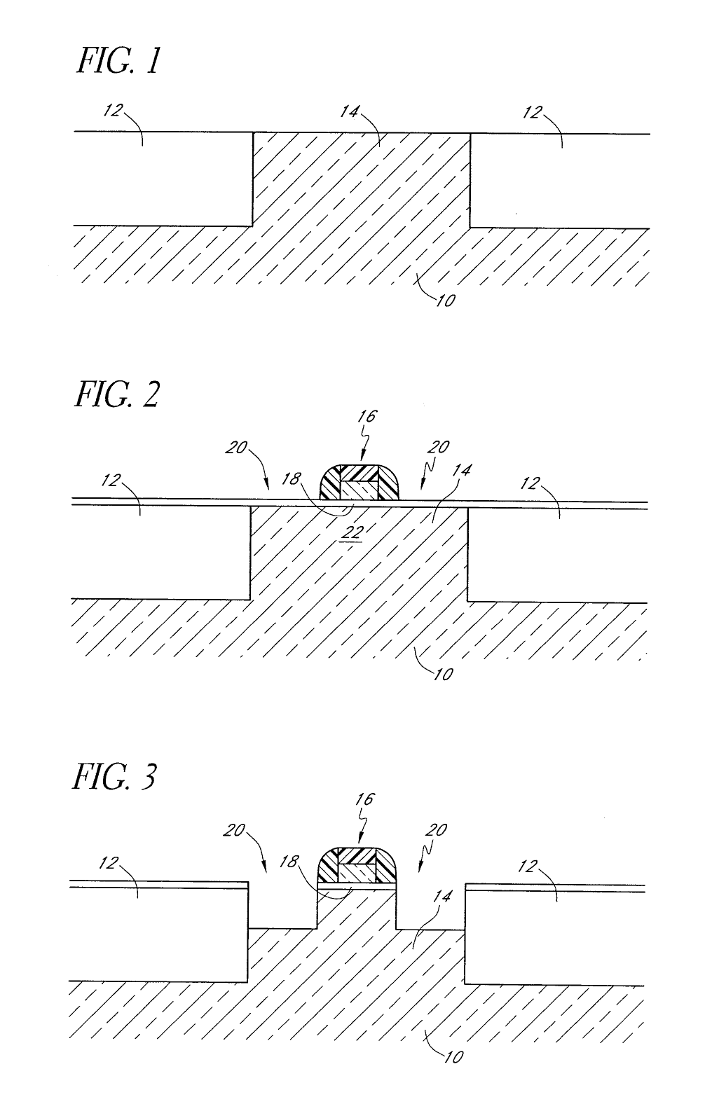

FIG. 1 shows a substrate 10 comprising a silicon wafer in the illustrated embodiment. The substrate 10 can include an epitaxial layer formed over a wafer or an SOI substrate. Field isolation regions 12 are formed by conventional shallow trench isolation (STI) techniques, defining active areas 14 in windows among the STI elements. Alternatively, any suitable method can be used to define field insulating material, including local oxidation of silicon (LOCOS) and a number of variations on LOCOS or STI. It will be understood that several active areas are typically defined simultaneously by STI across the substrate 10, and that the STI often forms a web separating transistor active areas 14 from one another. The substrate is preferably background doped at a level suitable for channel formation. In one embodiment (not shown), an epitaxial Si-containing layer is selectively deposited over the active area 14 by the methods described herein. The Si-containing layer may be, for example, boron-, phosphorous-, antimony-, indium-, or arsenic-doped silicon; Si:C, SiGe or SiGe:C. The selectively deposited epitaxial Si-containing layer may be strained or relaxed, and additional strained or relaxed layers may be deposited over the selectively deposited epitaxial Si-containing layer.

FIG. 2 illustrates the substrate 10 after formation of a gate electrode 16 over the active area 14. While illustrated as a traditional silicon electrode, surrounded by insulating spacers and cap layers, and separated from the underlying substrate 10 by a gate dielectric layer 18, it will be understood that the transistor gate stack can have any of a variety of configurations. In some process flows, for example, the spacers can be omitted. In the illustrated embodiment, the gate electrode 16 defines source and drain regions 20 on either side of the transistor gate electrode 16 within the active area 14. The gate electrode 16 also defines a channel region 22 under the gate electrode 16 and between the source and drain regions 20.

FIG. 3 illustrates the result of an etch step that selectively removes exposed silicon. Preferably a reactive ion etch (RIE) is employed to provide vertical sidewall definition and minimal damage to exposed oxide and nitride materials. Preferably the depth of the recesses is less than the critical thickness of the layer to be deposited in the recess, although strain on the channel can also be obtained by deposition greater than the critical thickness. As the exposed silicon is essentially the source and drain (S/D) regions 20 of the active area 14, the etch is referred to as a source/drain recess. It will be understood that, in some arrangements, a first step of clearing the thin dielectric over the source/drain regions 20 may be employed.

FIG. 4 shows the result of filling the recessed S/D regions 20 using a selective deposition process. In particular, the exposed semiconductor surfaces are cleaned, such as with an HF vapor or HF last dip, leaving a substantially oxygen-free surface for epitaxy thereover. The substrate 10 is disposed within a CVD chamber (not shown). A CVD condition is established in the CVD chamber, including flowing chlorine gas and a chloropolysilane to the chamber as disclosed hereinabove. Preferably, for the embodiment of FIGS. 1-5, germanium or carbon sources are included in order to create strain on the channel region, as described in more detail below. Preferably dopant hydrides are included in the process vapor mixture. A silicon-containing epitaxial layer grows selectively in the S/D regions 20. Advantageously, a selectively deposited, heteroepitaxial film 30 (e.g., Si:C or SiGe) fills the S/D regions 20 and exerts strain on the channel region 22. In the illustrated embodiment, the heteroepitaxial film 30 is approximately flush with the surface of the channel region 22.

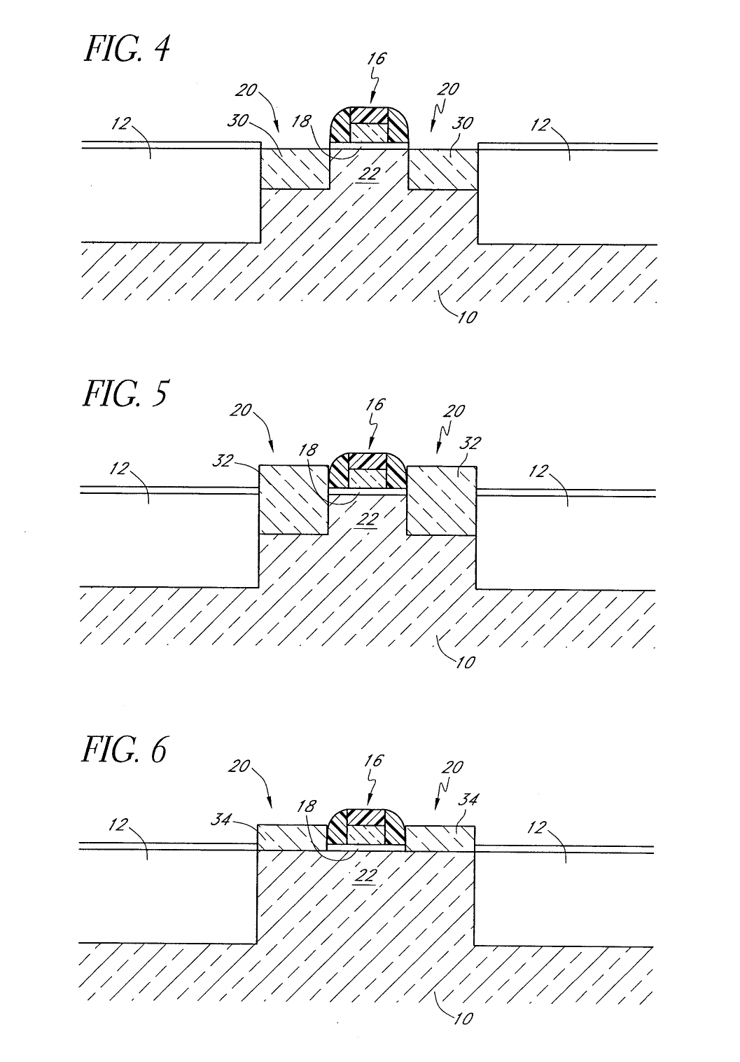

FIG. 5 illustrates an optional extension of the selective deposition to form elevated S/D regions 20 with the extended heteroepitaxial film 32. As the portion of the extended film 32 below the surface of the channel region 22 exerts lateral stress on the channel region 22, the portion above the surface of the substrate need not include as much or any lattice deviation from the natural silicon lattice constant. Accordingly, any germanium or carbon source gases, as the case may be, can be tapered or halted for the portion of the selective deposition above the surface of the channel region 22, and chloropolysilane flow continued. Electrical dopant source gases, particularly dopant hydrides such as arsine, phosphine or diborane, are preferably continued.

The elevated S/D structure 32 of FIG. 5 advantageously provides additional silicon material above the surface of the substrate 10. As is known in the art and informed by the guidance provided herein, through subsequent processing, insulating layers are deposited and contacts are made through the insulating film to the source and drain regions 20. The additional silicon material facilitates formation of silicide contacts, which reduce contact resistance (form ohmic contacts). Accordingly, nickel, cobalt or other metal may be deposited into the contact hole and allowed to consume the excess silicon without disturbing electrical properties of shallow junctions for the underlying source/drain regions 20.

FIG. 6 illustrates another embodiment, in which the structure of FIG. 2 is subjected to the selective deposition using flowing chlorine gas and a chloropolysilane, without the intervening S/D recess step. In this case, the selective deposition serves only to raise the source and drain regions, providing excess silicon 34 to permit consumption by contact silicidation without destroying shallow junctions. The deposition can optionally include dopant precursors to deposit doped silicon, e.g., silicon doped with an electrically active dopant. Dopants are unnecessary, however, if the entire excess silicon structure 34 is to be consumed by contact silicidation.

Advantageously, the selective nature of the chlorine/chloropolysilane deposition process obviates subsequent pattern and etch steps to remove excess deposition from over field regions. Even imperfect selectivity can advantageously permit use of a timed wet etch to remove unwanted deposition over insulating surfaces, rather than requiring an expensive mask step. Furthermore, superior film quality is obtained at relatively high deposition rates, improving throughput. For example, certain process embodiments may be used to selectively deposit boron-doped Si:Ge:C using chlorine, chloropolysilane, germane, methylsilane, and B₂H₆ to form, e.g., a base structure of a heterobipolar transistor (HBT). Other selective deposition process embodiments may be used to form an elevated source/drain (ESD) structure, a contact plug for DRAM and/or SRAM, using e.g., a chloropolysilane and chlorine at a deposition temperature in the range of about 400° C. to about 580° C. In some embodiments, intrinsic silicon is selectively deposited using a chloropolysilane and chlorine, in the substantial absence of a dopant precursor, e.g., in the substantial absence of a carbon source, germanium source or source of electrically active dopant.

Strain induced by Si:C films

Advantageously, depositions at high growth rates using chloropolysilane can enable extremely high levels of carbon. High levels of substitutional carbon incorporation into the silicon may be obtained by conducting the deposition at a relatively high growth rate using chloropolysilane and a carbon source (and, in some embodiments, an optional dopant precursor for an electrically active dopant), whether or not selective. Under preferred deposition conditions, carbon incorporation levels may be between about 1.0% and 3.5%.

As is known in the art, the lattice constant for single crystal silicon is about 5.431 Å, whereas single crystal carbon in the form of diamond has a lattice constant of 3.567 due to the small size of the carbon atoms. Accordingly, tensile strain may be introduced into single crystalline silicon by substitutional doping with carbon, because carbon atoms are smaller than the silicon atoms that they replace. The amount of substitutional carbon in silicon may be determined by measuring the perpendicular lattice spacing of the doped silicon by x-ray diffraction, then applying Vegard's law (linear interpolation between single crystal silicon and single crystal diamond). Those skilled in the art are aware of Vegard's law and the relationships between substitutional carbon level, lattice spacing and strain. See, e.g., Judy L. Hoyt, “Substitutional Carbon Incorporation and Electronic Characterization of Si_{1-y}Cy/Si and Si_{1-x-y}GeₓCy/Si Heterojunctions,” Chapter 3 in “Silicon-Germanium Carbon Alloy,” Taylor and Francis, NY, pp. 59-89, 2002, the disclosure of which is incorporated herein by reference. As illustrated in FIG. 3.10 at page 73 of the aforementioned article by Hoyt, prior deposition methods have provided silicon having a substitutional carbon content of up to 2.3%, which corresponds to a lattice spacing of over 5.4 Å and a tensile stress of less than 1.0 GPa. FIG. 3.10 also illustrates that the total carbon content in the doped silicon may be determined by SIMS, and thus that the non-substitutional carbon content may be determined by subtracting the substitutional carbon content from the total carbon content.

A lattice spacing of about 5.323 Å (as measured by X-ray diffraction) may be achieved for silicon substitutionally doped with carbon (herein, “Si:C”) deposited from chloropolysilane, arsine and a carbon source (e.g., monomethyl silane). This lattice spacing of 5.323 Å corresponds to a substitutional carbon level of about 3.25%. When constrained to an underlying silicon template (e.g., lattice spacing about 5.43 Å), the tensile stress in such Si:C layers amounts to about 2.06 GPa. More generally, the stress produced is preferably between 1 GPa and 3 GPa. The deviation from silicon's natural lattice constant introduces stress and a corresponding strain that advantageously improves electrical carrier mobility in semiconductors, improving device characteristics and/or performance. When the Si:C is deposited to less than the critical thickness of the material, the deposited layer remains tensile strained and electron mobility is improved for NMOS devices. In this case, the deposited Si:C layer can be selectively formed e.g., in recessed source/drain regions having a channel between. In the embodiments of FIGS. 1-5, however, the Si:C layer is selectively formed in recessed source/drain regions 20, and is preferably deposited under conditions (thickness, temperature) that maintain stress. The smaller lattice constant of the Si:C material filling the S/D recesses exerts tensile strain on the channel region 22 therebetween. Preferably a dopant hydride is added to the process flow, in addition to the chloropolysilane and carbon source. Preferably arsine or phosphine are employed. The selectively deposited single crystalline silicon film comprises from about 1.0 atomic percent to about 3.5 atomic percent of substitutional carbon and has a lattice spacing of 5.38 Å or less, preferably about 5.36 Å or less, more preferably about 5.34 Å or less. Such single crystalline silicon films may further comprise an electrically active dopant (such as phosphorous or arsenic). When doped (preferably substitutionally doped) with an electrically active dopant, the single crystalline silicon film comprising substitutional carbon may have having a resistivity of about 1.0 mΩcm or less, preferably about 0.7 mΩcm or less. The percentage of substitutional carbon for the silicon films described herein is determined by x-ray diffraction and Vegard's Law (linear interpolation between silicon and carbon as discussed above), and is expressed as atomic % on a whole film basis, unless otherwise indicated.

Such single crystalline silicon film comprising substitutional carbon may be formed by a relatively high rate deposition process using chlorine, a chloropolysilane, a carbon precursor and, optionally, a dopant precursor for an electrically active dopant. High levels of substitutional carbon may be achieved using chloropolysilane by carrying out the depositions at a relatively high deposition or growth rate, e.g., at least about 5 nm/min, preferably at least about 15 nm/min, more preferably at least about 20 nm/min. The growth rates may be controlled, e.g., by controlling the chloropolysilane flow rates and temperatures, to produce single crystalline films that comprise various levels of carbon, e.g., 2.5% or greater substitutional carbon, preferably 2.6% or greater substitutional carbon, more preferably 2.7% or greater substitutional carbon. In some embodiments, the single crystalline films may comprise even higher levels of carbon, e.g., 2.8% or greater substitutional carbon, preferably 2.9% or greater substitutional carbon, more preferably 3.0% or greater substitutional carbon. Higher deposition rates tend to produce higher levels of substitutional carbon, for a given set of deposition parameters. However, excessive deposition temperatures tend to increase the tendency for carbon to precipitate out of substitutional sites and aggregate or cluster to form non-substitutional silicon carbide inclusions, reducing substitutional carbon levels. Preferred deposition temperatures are generally in the range of about 500° C. to about 580° C., depending on the amount of substitutional carbon desired. This invention is not bound by theory of operation, but embodiments of the methods described herein are believed to be particularly advantageous because they enable relatively low temperature, high rate depositions. To achieve high levels of substitutional carbon, it is desirable to conduct the deposition at a relatively high rate to trap the carbon in substitutional sites before it can diffuse to interstitial sites. However, higher rate depositions are typically achieved by increasing deposition temperature, which tends to increase the rate of carbon diffusion out of substitutional sites. Therefore, prior deposition methods generally involved a trade-off between diffusion and deposition rate that limited the amount of substitutional carbon incorporated into Si-containing films. Surprisingly, embodiments of the methods described herein enable relatively fast deposition (trapping carbon in substitutional sites) at relatively low temperatures (slowing diffusion away from the substitutional sites), thereby enabling increased amounts of substitutional carbon to be incorporated into single crystal Si-containing films. Preferred embodiments utilize a chloropolysilane (e.g., comprising at least one of monochlorodisilane, dichlorodisilane, trichlorodisilane, and tetrachlorodisilane) in combination with a carbon source (e.g., MMS) and a deposition temperature in the range of about 400° C. to about 580° C.

A single crystalline silicon film comprising relatively high levels of substitutional carbon as described herein (e.g., films comprising 2.4% or greater substitutional carbon) may exhibit various levels of tensile stress because the substitutional carbon atoms are smaller than the silicon atoms that they replace in the crystalline silicon lattice structure. In an embodiment, a single crystalline silicon film comprising 2.4% or greater substitutional carbon has a tensile stress of about 1.0 GPa or greater, e.g., about 1.5 GPa or greater, preferably about 1.7 GPa or greater, more preferably about 1.85 GPa or greater, even more preferably about 2.0 GPa or greater. The stress may be determined in any particular direction within the film. For example, for overlying silicon films comprising substitutional carbon that are deposited onto underlying crystalline silicon substrates, the overlying silicon film may exhibit a perpendicular stress (i.e., stress measured perpendicular to the film/substrate interface) that is different from the parallel stress (i.e., stress measured parallel to the film substrate interface). See, e.g., FIG. 3.1 at page 62 of the aforementioned article by Hoyt.

The thickness of a strained single crystalline silicon film comprising substitutional carbon as described herein is preferably less than a critical film thickness. Those skilled in the art understand that a critical film thickness is a film thickness at which a strained film relaxes under a particular set of conditions. As the concentration of substitutional dopant increases, the critical thickness generally decreases. Films having a thickness less than the critical thickness typically remain strained under those conditions. For example, a single crystalline silicon film comprising about 1.8% substitutional carbon may have a critical thickness of about 200 nm, whereas an otherwise similar film comprising 3.5% substitutional carbon may have a critical thickness of about 25-30 nm, depending on the temperature. Films having a thickness that is less than a critical thickness for that film will tend to remain strained unless or until sufficiently perturbed (e.g., exposed to sufficient heat to cause relaxation).

Thus, relatively high levels of substitutional carbon may be incorporated into a selectively deposited silicon film by depositing the film using chlorine and chloropolysilane at a deposition rate of at least about 5 nm per minute, preferably at least about 15 nm per minute. Various deposition parameters may be used to control the deposition rate and the level of substitutional carbon incorporated into the resulting silicon film. Higher levels of substitutional carbon may be achieved at higher chamber pressures, lower chlorine flows and lower carrier gas flows. In certain embodiments, relatively higher growth rates may be achieved at chamber pressures in the range of about 10 Torr to about 100 Torr and higher growth rates are obtained with lower carrier gas flow rates.

As the flow rate ratio of chloropolysilane to carbon source is increased, the amount of substitutional carbon in resulting film tends to decrease. Relatively high levels of substitutional carbon may be achieved at a growth rate of 5 nm per minute. In some embodiments, higher growth rates (resulting from higher chloropolysilane flow rates and lower chlorine flow rates) do not result in higher substitutional carbon because the flow rate ratio of chloropolysilane to carbon source increases (thereby decreasing the relative amount of carbon available for incorporation into the film). Under certain conditions, higher substitutional carbon levels may be obtained at higher relative carbon source (e.g., monomethyl silane or MMS) flow rates. As the flow rate ratio of MMS to chloropolysilane increases, the amount of substitutional carbon in the resulting film increases, in some cases relatively linearly. Higher levels of substitutional carbon may be achieved at relatively higher growth rates, and higher growth rates may be obtained at relatively higher chamber pressures, higher carbon and chloropolysilane flow rates, and lower chlorine flow rates. Thus, under selected conditions, higher levels of substitutional carbon may be obtained with higher growth rates; in some configurations, growth rate is a strong positive function of chloropolysilane flow rate, and chamber pressure has a relatively modest effect. Thus, high deposition rates may be used to achieve high levels of substitutional carbon in selectively deposited single crystalline silicon.

The chemical vapor deposition conditions used to selectively deposit a single crystalline silicon film that comprises at least 2.4% substitutional carbon preferably include a deposition temperature that is at about a transition temperature between substantially mass-transport controlled deposition conditions and substantially kinetically controlled deposition conditions for the chloropolysilane. At temperatures higher than about the transition temperature, the deposition conditions are substantially mass-transport controlled. In some cases, at deposition temperatures higher than about 550° C., certain aspects of film quality may be reduced. The position of the transition temperature may be changed by manipulating the deposition conditions, e.g., by varying the chamber pressure and carrier gas flow rate, and by the selection of the chloropolysilane, e.g., the chlorine:hydrogen molar ratio and the chlorine flow rate. In some embodiments, the chemical vapor deposition conditions comprise a temperature in the range of about 500° C. to about 580° C. In some embodiments, the chemical vapor deposition conditions comprise a chamber pressure of at least about 500 mTorr, preferably at least about 5 Torr, e.g., in the range of about 20 Torr to about 800 Torr.

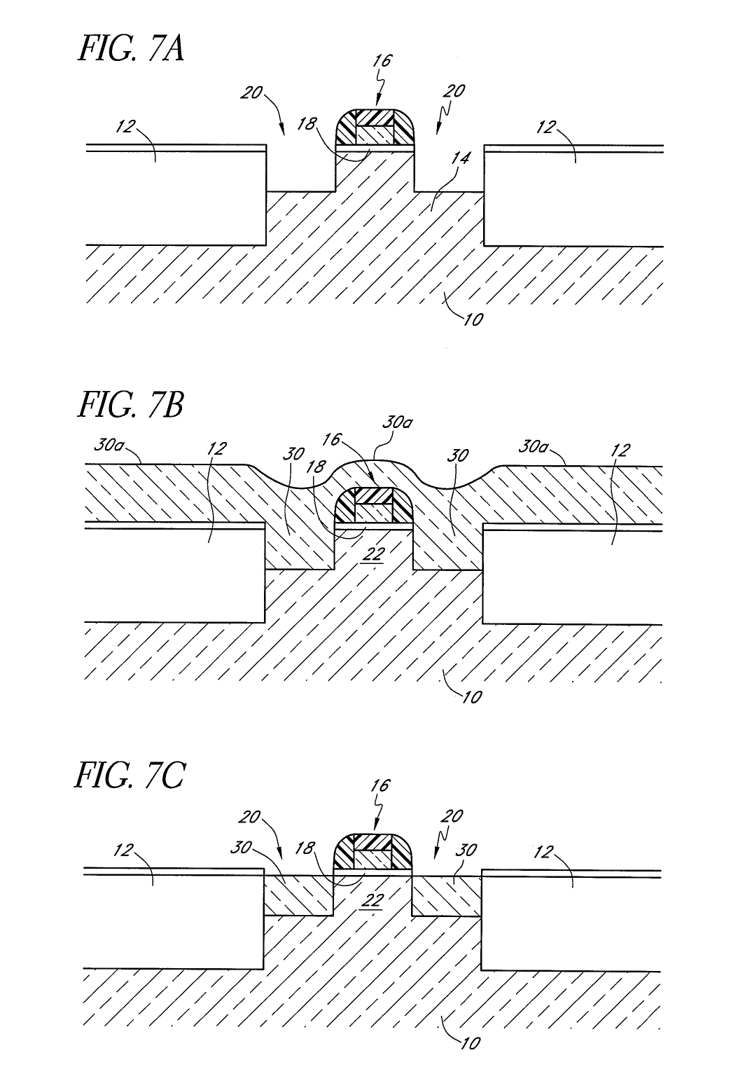

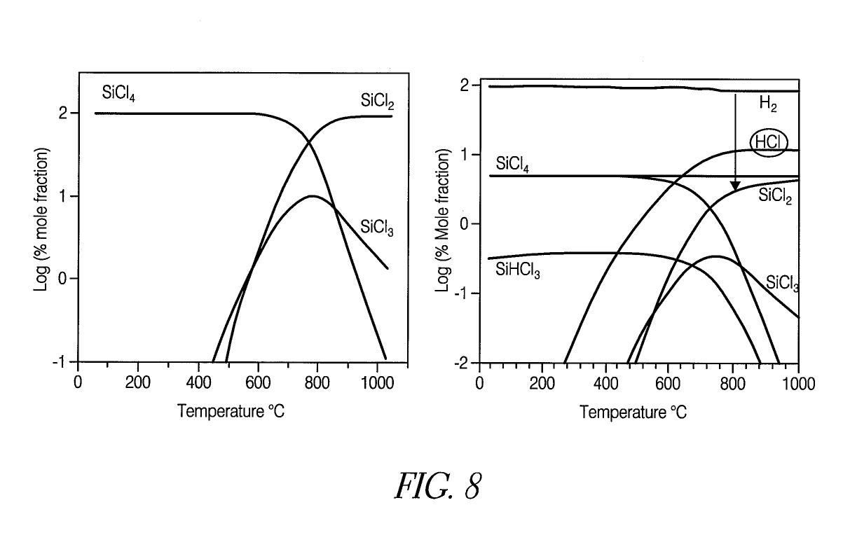

In the embodiments of FIGS. 1-5, a Si:C layer may be selectively formed in recessed source/drain regions 20. However, the Si:C layer may also be formed by a non-selective process that involves a blanket deposition of the Si:C layer, followed by in situ or ex situ etching so that single crystalline Si:C remains in the recessed source/drain regions 20. An embodiment of such a process is illustrated by the sequence shown in FIG. 7. The structure depicted in FIG. 7A is essentially identical to the structure shown in FIG. 3 and may be formed in the same manner. In contrast to the selective deposition process illustrated in FIG. 4 however, FIG. 7B shows the result of a blanket deposition process in which a heteroepitaxial Si:C film 30 fills the source/drains regions 20, and in which a polycrystalline Si:C film 30ais deposited over the field isolation regions 12 and the gate electrode 16. The methods described above for depositing a single crystalline silicon film that comprises at least 2.4% substitutional carbon may be employed to deposit the single crystalline Si:C film 30 and the polycrystalline Si:C film 30a, except that chlorine flows and the chlorine content of the chloropolysilane are preferably minimized to reduce selectivity. The single crystalline Si:C film 30 is preferably deposited under conditions (thickness, temperature) that maintain stress. As discussed above, the smaller lattice constant of the Si:C material filling the source/drain recesses exerts tensile strain on the channel region 22 therebetween. Preferably a dopant hydride, more preferably, an n-type dopant hydride, is added to the process flow, in addition to chloropolysilane and carbon source. Preferably phosphine is employed.

FIG. 7C is similar to FIG. 4 above, except that the depicted structure results from removing the polycrystalline Si:C film 30a using etching conditions that are selective for the removal of polycrystalline silicon against single crystal silicon. Such etching conditions are known to those skilled in the art. The process illustrated in FIG. 7 may be used in various situations in which it is desirable to exert a tensile stress on a single crystalline Si-containing region (such as the channel region 22), and particularly to increase the carrier mobility in the tensile stressed region (the region to which the tensile stress is applied, such as the channel region 22). Preferably, the carrier mobility (e.g., hole mobility or electron mobility) is increased by at least about 10%, more preferably by at least about 20%, as compared to a comparable region that is substantially identical to the tensile stressed region except that it is not tensile stressed.

Silicon Films Containing Electrically Active Dopants

The methods described above for the incorporation of substitutional carbon into selectively deposited silicon films may also be used for substitutional doping of silicon using other dopants, such as electrically active dopants. High levels of substitutional doping may be used to produce silicon films having low resistivity. In an embodiment, the resulting single crystalline silicon film have a resistivity of about 1.0 mΩ·cm or less and comprise at least about 3×10²⁰ cm³ of a substitutional dopant, preferably at least about 4×10²⁰ cm⁻³ of a substitutional dopant, more preferably at least about 5×10²⁰ cm⁻³ of a substitutional dopant. The level and type of electrically active dopant may be varied to produce resistivity values in the resulting doped silicon that are 1.0 mΩ·cm or less, e.g., 0.9 mΩ·cm or less, preferably 0.8 mΩ·cm or less, more preferably 0.7 mΩ·cm or less, even more preferably 0.6 mΩ·cm or less, most preferably 0.5 mΩ·cm or less, as desired for a particular application. By using the appropriate dopant precursor, the method may be used to produce silicon films that contain n-type dopants or p-type dopants. Preferably, n-type dopants are employed with carbon-doped silicon films. Examples of suitable dopant precursors and dopants are discussed above. The deposition rate may also be increased, e.g., to at least about 10 nm per minute, or preferably to at least about 20 nm per minute.

Chemical vapor deposition conditions suitable for depositing a silicon film that is substitutionally doped are generally compatible with the CVD conditions described above for the selective deposition of silicon films substitutionally doped with carbon. Silicon film resistivity values of about 1.0 mΩ·cm or less may be achieved using chlorine and a chloropolysilane by conducting the depositions at a relatively high rate in the general manner described above, e.g., at least about 5 nm per minute, more preferably at least about 15 nm per minute. The growth rate of doped silicon films tends to be a substantially linear function of the flow rate of the chloropolysilane and the dopant precursor. For a given chloropolysilane flow rate, decreases in the resistivity of a Si-containing film are not necessarily achieved by merely increasing the flow rate of the dopant precursor. For example, in some situations increasing dopant precursor flow rate may result in increasing resistivity due to the incorporation of an increasing fraction of electrically inactive dopant.

In some embodiments, the use of chloropolysilane enables relatively high rate depositions that in turn enable surprisingly high levels of substitutional doping electrically active dopants. Deposition methods using chloropolysilane as taught herein are generally relatively insensitive to the nature of the dopant or dopant precursor. Thus, although the above examples focus on SiC, the deposition methods using chloropolysilane that are described herein, and particularly the high rate deposition methods, are applicable to a wide variety of dopants (such as carbon, germanium and electrically active dopants), and to the incorporation of those dopants into a wide variety of Si-containing materials (such as Si, Si:C, SiGe, Si:Ge:C, etc.). Routine experimentation may be used to high rate deposition conditions applicable to a particular Si-containing material.

Strain Induced by SiGe Films

Advantageously, selective deposition using chloropolysilane is also effective for incorporating germanium substitutionally into epitaxial films, for creating strain with SiGe layers. Under preferred deposition conditions, germanium incorporation levels can be between about 1% and 99%, typically between 17% and 50%, often between about 20% and about 50%, and more particularly between about 20% and 40%, e.g., to exert a stress on a channel.

As is known in the art, the lattice constant for single crystal silicon is about 5.431 Å, whereas single crystal germanium has a lattice constant of 5.657 due to the larger size of the germanium atoms. The deviation from silicon's natural lattice constant introduces strain that advantageously improves electrical carrier mobility in semiconductors, improving device efficiency. When the SiGe is deposited to less than the critical thickness of the material, the deposited layer remains compressively strained and hole mobility is improved for PMOS devices. In this case, the deposited SiGe layer can be selectively formed over the entire active area and can define the channel, or it can act as a relaxed template for forming a tensile strained silicon layer thereover, which can then itself serve as a channel region.

In the embodiments of FIGS. 1-5, however, the SiGe layer is selectively formed in recessed source/drain regions 20, and is preferably deposited under conditions (thickness, temperature) that maintain stress. The larger lattice constant of the SiGe material filling the S/D recesses exerts compressive strain on the channel region 22 therebetween. Preferably a dopant hydride is added to the process flow, in addition to chlorine gas, the chloropolysilane and the germanium source. Preferably a p-type dopant, and more preferably diborane, is employed.

The methods described above for the incorporation of substitutional carbon into silicon may also be used to incorporate substitutional carbon into SiGe and to incorporate substitutional germanium into Si:C.

Non-Hydrogen Carrier Gas

In accordance with another aspect of the invention, a non-hydrogen carrier gas is preferably employed in combination with a chloropolysilane to conduct a deposition as generally described above. Hydrogen gas (H₂) is the most popular carrier gas employed in vapor deposition for semiconductor processing, and particularly in epitaxial deposition. There are several reasons for the popularity of H₂. H₂ can be provided with a high degree of purity. Furthermore, the thermal properties of hydrogen are such that it does not have as great a thermal effect on the wafer as other inert gases (e.g., noble gases) might. Additionally, hydrogen has a tendency to act as a reducing agent, such that it combats the formation of native oxide that results from less than perfect sealing of the reaction chamber.

However, the inventors have found particular advantages from employing a non-hydrogen carrier gas in the chloropolysilane deposition system described herein. Preferably helium (He), argon (Ar), neon (Ne), xenon (Xe) or nitrogen gas (N₂), or a combination of such inert gases, is employed in place of hydrogen. In a preferred embodiment, He is employed as a carrier gas, as it has thermal behavior close to that of H₂ and thus entails less tuning of the reactor for the adjustment from the use of H₂ carrier gas.

There are a number of possible reaction mechanisms in such a chloropolysilane/hydrogen system. For example, when the chloropolysilane is tetrachlorodisilane (Si₂H₂Cl₄), the possible reactions include those represented above by equations (1d) to (8d), (1e) to (3e), (1f) and in some embodiments by equations (1g) to (16g). As discussed above, selective CVD conditions are such that etching dominates over insulating surfaces while deposition dominates over semiconductor windows. It is desirable for the chloropolysilane to be sufficiently chlorinated to reduce reactivity with chlorine and to be a source of at least two of :SiHCl, :SiH₂ and :SiCl₂ for deposition.

However, when free H₂ is present in large quantities (e.g., as a carrier gas), the reaction of equation (6g) takes place, generating HCl. Increasing the concentration of HCl in the system drives equations (1e) to (3e) in the reverse direction, thus driving down deposition rates for any given “tuned” process. A tuned process represents one in which the reactant concentrations have been tuned to achieve selective deposition.

Equation (4g) illustrates yet another desirable reaction that is depressed by the generation of HCl due to the presence of H₂ carrier gas. Equation (4g) illustrates removal of chlorine adsorbed on the wafer surface. Dopant hydrides, such as arsine, phosphine and diborane (phosphine shown) tend to react with surface chlorine atoms and form volatile byproduct, such that surface reaction sites are freed for depositions. As with equations (1e) to (3e), however, increasing the HCl concentration tends to depress the desirable removal reaction by shifting the equilibrium for equation (4g) to the left.

Accordingly, the use of a non-hydrogen carrier gas (which is generally the dominant gas in the system) will avoid the consumption of Cl₂ and the generation of HCl by equation (6g) and thereby avoid depressing the deposition reactions (1e) to (3e) and the removal reaction (4g). FIG. 8, the data for which is taken from Violette et al., J. Electrochem. Soc., Vol. 143 (1996), pp. 3290-3296 and O'Neill et al., J. Electrochem. Soc., Vol. 144 (1997), pp. 3309-3315 (both of which are hereby incorporated by reference), dramatically illustrates how the addition of H₂ carrier gas depresses the concentration of deposition reactant SiCl₂ in the DCS/Cl₂ of their studies. Note that, while the process preferably employs no H₂, the benefits of minimizing H₂ can be obtained without total exclusion. Preferably the main carrier gas, representing the largest source of gas in the system is non-hydrogen. In other words, to the extent H₂ is provided, it preferably represents a minority of the carrier gas (e.g., as a carrier or diluent for dopant gas only).

Chloropolysilane Deposition System

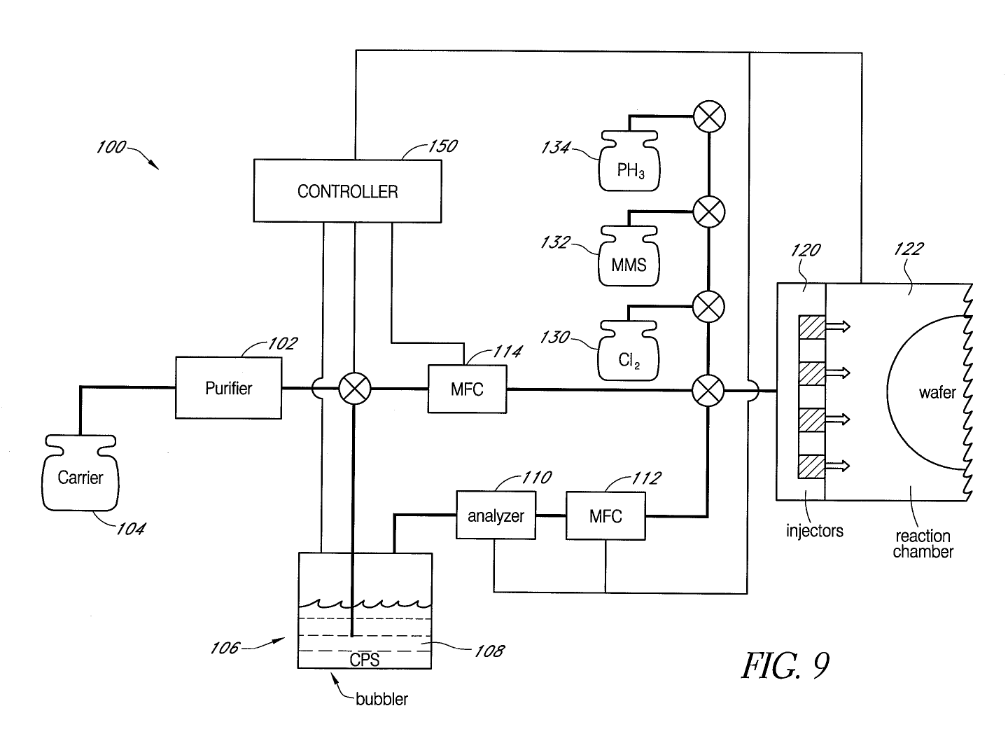

FIG. 9 illustrates a preferred reactor system 100 employing chlorine gas, a carrier gas (helium in the illustrated embodiment), and a chloropolysilane (a mixture consisting essentially of 75% by weight dichlorodisilane and 25% by weight trichlorodisilane in the illustrated embodiment). As shown, a purifier 102 is positioned downstream of the helium source 104. Some of the inert gas flow is shunted to a bubbler 106, from which the carrier gas carries vaporized chloropolysilane (CPS) 108. Alternatively, the CPS can be simply heated to increase the vapor pressure of CPS in the space above the liquid, and the carrier gas picks up the CPS as it passes through that space. In any case, downstream of the liquid reactant source container 106 is an analyzer 110 that determines, by measuring the speed of sound through the vapor, the reactant concentration of the flowing gas. Based upon that measurement, the setpoint for the software-controlled downstream mass flow controller (MFC) 112 is altered by the analyzer 110. Such analyzers are commercially available.

The flow through this MFC 112 merges with the main carrier gas through the main carrier gas MFC 114 and other reactants at the gas panel, upstream of the injection manifold 120 for the deposition chamber 122. A container holding chlorine gas 130 is also provided. In the illustrated embodiment, a source for carbon 132 (illustrated as monomethyl silane or MMS) and a source for dopant hydride 134 (PH₃ shown) are also provided. The reactor system 100 may (optionally) further comprise a container holding a silicon source such as silane, disilane and/or trisilane (not illustrated in FIG. 9). Such a silicon source may be in place of, or in addition to, the carbon source 132, and thus may be configured similarly.

As illustrated, the reactor system 100 also includes a controller 150, electrically connected to the various controllable components of the system 100. The controller 150 is programmed to provide gas flows, temperatures, pressures, etc., to practice the deposition processes as described herein upon a substrate housed within the reaction chamber 122. As will be appreciated by the skilled artisan, the controller 150 is a computer that typically includes a memory and a microprocessor, and may be programmed by software, hardwired or a combination of the two, and the functionality of the controller 150 may be distributed among processors located in different physical locations. Accordingly, the controller 150 can also represent a plurality of controllers distributed through the system 100.

Accordingly, the combination of chlorine/chloropolysilane/non-hydrogen carrier gas results in selectivity and enhanced deposition rates for silicon-containing materials, particularly epitaxial layers. In one embodiment, the gas flow rates are selected, in combination with pressure and temperature, to achieve selective deposition on/in semiconductor windows among insulating material. It will be appreciated that a hydrogen carrier gas may be used in place of the helium source 104. In the illustrated embodiment, the carbon source 132 is also provided, and in combination with chloropolysilane, high substitutional carbon content can be achieved, as disclosed hereinabove. In another embodiment, the dopant hydride source 134 is preferably also provided to result in in situ doped semiconductor layers with enhanced conductivity. Preferably, for selective silicon or Si:C epitaxy, the dopant hydride is arsine or phosphine, and the layer is n-type doped. Most preferably the diluent inert gas for the dopant hydride is also a non-hydrogen inert gas. Thus, phosphine (PH₃) and MMS are preferably stored at their source containers 132, 134 in, e.g., helium. Typical dopant hydride concentrations are 0.1% to 5% in helium, more typically 0.5% to 1.0% in helium for arsine and phosphine. Typical carbon source concentrations are 5% to 50% in helium, more typically 10% to 30% in helium.

### Example 1

This example illustrates the deposition of selective epitaxial silicon films over mixed morphology substrates.

An eight-inch unpatterned Si<100> wafer substrate and separate wafer with a fully oxidized (1000′) surface are serially loaded into and processed in an Epsilon E2500™ reactor system. The substrates are each introduced into the reactor system at 900° C., a hydrogen flow rate of 20 slm is used initially for the bare wafer, and the substrate is allowed to stabilize for 1 minute. The hydrogen flow is then shut down as the temperature of the substrate is reduced to 550° C. The substrate is then allowed to stabilize for 10 seconds, after which time a flow of 20 standard cubic centimeters per minute (sccm) of chloropolysilane (a mixture consisting essentially of 75% by weight dichlorodisilane and 25% by weight trichlorodisilane) and a flow of 12.5 sccm of chlorine is introduced at a deposition pressure of 64 Torr for about 3 minutes. A continuous, uniform silicon film having a thickness of about 450 Å is deposited over the single crystal wafer, while the separately processed oxidized wafer shows essentially no deposition under identical conditions. Each substrate is removed from the reactor and returned to the loadlock after its deposition step. A silicon film having excellent epitaxial quality is observed on the silicon wafer while no deposition is observed on the oxide substrate.

### Example 2

Deposition conditions are varied to identify a selective CVD condition as follows: A quartz tube furnace is heated to temperature of about 550° C. A flow of 20 sccm of chloropolysilane (a mixture consisting essentially of 75% by weight dichlorodisilane and 25% by weight trichlorodisilane) and a flow of 75 sccm of chlorine is introduced to the quartz tube furnace in the absence of a carrier gas at a deposition pressure of 64 Torr. No deposition is observed. Since the furnace is quartz, deposition on the walls is indicative of CVD conditions on an oxide surface, and thus it is apparent that this is likely to be an etching condition for oxide surfaces. The chlorine flow is reduced in stages to about 12.5 sccm over the course of about 5-6 minutes, at which time a deposit (silicon) forms on the walls of the furnace, indicating that deposition is less selective than at higher chlorine flow rates. Thus, under these conditions, this CVD condition is likely to be selective on a mixed substrate at a chlorine flow somewhat higher than 12.5 sccm. The chlorine flow is further reduced in stages to about 5 sccm over the course of about 3.5 minutes, during which deposition on the chamber walls is observed to continue. The chlorine flow rate is then increased to about 20 sccm and maintained for about 45 seconds, during which time there is no additional deposition on the walls of the chamber, confirming that this deposition is under a selective CVD condition. The chloropolysilane flow rate is then reduced to zero for about 16 seconds, during which time the deposited silicon film is removed, providing further confirmation that the previous deposition condition had been selective.

### Example 3

Deposition conditions are varied to identify a selective CVD condition as described in EXAMPLE 2, except that the deposition temperature is 500° C., the deposition pressure is 4 Torr, and a 300 sccm helium carrier gas is used. As in EXAMPLE 2, the chloropolysilane flow is 20 sccm and the initial chlorine flow rate is 75 sccm. At this initial condition, no deposition is observed, and thus it is apparent that this is likely to be an etching condition for oxide surfaces. The chlorine flow is reduced in stages to about 20 sccm, at which time a slight deposit (silicon) begins to form on the walls of the furnace, indicating that deposition is less selective than at higher chlorine flow rates. Thus, under these conditions, this CVD condition is likely to be selective on a mixed substrate at a chlorine flow slightly higher than about 20 sccm. The deposition becomes progressively heavier as the chlorine flow is reduced in stages to about 2.5 sccm, then progressively lighter as the chlorine flow is increased back up to about 20 sccm, confirming that this CVD condition is likely to be selective on a mixed substrate at a chlorine flow slightly higher than about 20 sccm.

All patents, patent applications and publications mentioned herein are hereby incorporated by reference in their entireties. It will be appreciated by those skilled in the art that various omissions, additions and modifications may be made to the processes described above without departing from the scope of the invention, and all such modifications and changes are intended to fall within the scope of the invention, as defined by the appended claims.

What is claimed is:

1. A method of selectively depositing a Si-containing film, comprising:
establishing a selective chemical vapor deposition (CVD) condition in a CVD chamber, wherein establishing the selective CVD condition comprises flowing a chloropolysilane from a container to the CVD chamber and flowing a chlorine gas to the CVD chamber, the chloropolysilane comprising at least one of monochlorodisilane, dichlorodisilane, trichlorodisilane, and tetrachlorodisilane; and
selectively depositing a Si-containing film onto a single crystal surface region of a substrate disposed within the CVD chamber under the selective CVD condition while minimizing deposition onto a non-single crystalline surface region of the substrate during the selective deposition.

2. The method of claim 1, wherein establishing the selective CVD condition comprises minimizing flowing hydrogen to the CVD chamber.

3. The method of claim 1, wherein establishing the selective CVD condition comprises minimizing flowing hydrogen chloride to the CVD chamber.

4. The method of claim 1, wherein the tetrachlorodisilane is 1,1,1,2-tetrachlorodisilane.

5. The method of claim 1, wherein the trichlorodisilane is 1,1,1,-trichlorodisilane.

6. The method of claim 1, wherein establishing the selective CVD condition comprises flowing the chloropolysilane to the CVD chamber at a flow rate that is effective to selectively deposit the Si-containing film onto the substrate at a deposition rate of at least about 140 Å per minute.

7. The method of claim 1, wherein establishing the selective CVD condition comprises heating the chloropolysilane in the CVD chamber under decomposition conditions selected to form reactive intermediates comprising at least two of :SiHCl, :SiH₂ and :SiCl₂.

8. The method of claim 1, wherein the selective CVD condition comprises a substrate temperature in the range of about 400° C. to about 580° C.

9. The method of claim 1, wherein the selective CVD condition comprises a CVD chamber pressure in the range of about 20 Torr to about 760 Torr.

10. The method of claim 1, wherein minimizing deposition onto the non-single crystalline surface region comprises depositing substantially no Si-containing material onto the non-single crystalline surface region during the selective deposition.

11. The method of claim 1, wherein the selective CVD condition comprises a substrate temperature that is effective to epitaxially or heteroepitaxially deposit the Si-containing film onto the single crystal surface region of the substrate.

12. The method of claim 11, wherein establishing the selective CVD condition comprises flowing a carbon source to the CVD chamber.

13. The method of claim 12, wherein the carbon source is selected from monosilylmethane, disilylmethane, trisilylmethane, tetrasilylmethane, monomethyl silane, dimethyl silane, and 1,3-disilabutane.

14. The method of claim 12, wherein the selective CVD condition further comprises a deposition temperature and a carbon source flow rate that are effective to incorporate from about 1.0 atomic % to about 3.5 atomic % of substitutional carbon into the selectively deposited Si-containing film.

15. The method of claim 1, wherein establishing the selective CVD condition comprises flowing at least one second chloropolysilane to the CVD chamber, the second chloropolysilane being different from said chloropolysilane.

16. The method of claim 15, comprising flowing said chloropolysilane and the second chloropolysilane from the container.

17. The method of claim 16, wherein said chloropolysilane and the second chloropolysilane are present in the container at a weight ratio in the range of about 1:9 to about 9:1.

18. The method of claim 15, wherein the second chloropolysilane comprises at least one selected from monochlorodisilane, dichlorodisilane, trichlorodisilane, tetrachlorodisilane, pentachlorodisilane, hexachlorodisilane, chlorotrisilane, dichlorotrisilane, trichlorotrisilane, tetrachlorotrisilane, pentachlorotrisilane, hexachlorotrisilane, heptachlorotrisilane, and octachlorotrisilane.

19. The method of claim 18, wherein said chloropolysilane comprises dichlorodisilane and the second chloropolysilane comprises trichlorodisilane.

20. The method of claim 15, comprising flowing a third chloropolysilane to the CVD chamber, the third chloropolysilane being different from the second chloropolysilane and different from said chloropolysilane.

21. The method of claim 1, wherein establishing the selective CVD condition comprises flowing a silicon source to the CVD chamber, the silicon source comprising at least one of disilane and trisilane.

22. The method of claim 1, wherein the CVD chamber is included in a horizontal flow, single wafer reactor.

23. The method of claim 1, wherein the substrate comprises an integrated circuit.

24. The method of claim 1, wherein establishing the selective CVD condition comprises flowing a germanium precursor to the CVD chamber.

25. The method of claim 24, wherein the germanium precursor comprises at least one of germane, monochlorogermane, dichlorogermane, trichlorogermane, tetrachlorogermane, digermane, chlorodigermane, dichlorodigermane, trichlorodigermane, tetrachlorodigermane, pentachlorodigermane, and hexachlorodigermane.

26. The method of claim 1, wherein establishing the selective CVD condition comprises flowing an electrically active dopant precursor to the CVD chamber under the chemical vapor deposition conditions.

27. The method of claim 26, wherein the electrically active dopant precursor comprises at least one of boron, phosphorous, arsenic, indium and antimony.

28. The method of claim 1, wherein the selectively deposited Si-containing film is strained.

29. The method of claim 28, wherein the selectively deposited Si-containing film is compressively strained.

30. The method of claim 28, wherein the selectively deposited Si-containing film is tensile strained.

31. A deposition system, comprising:
a chemical vapor deposition (CVD) chamber configured to hold a substrate therein;
a chloropolysilane, wherein the chloropolysilane comprises at least one of monochlorodisilane, dichlorodisilane, trichlorodisilane, and tetrachlorodisilane;
a chlorine gas;
a first container holding the chloropolysilane, the first container being operatively connected to supply the chloropolysilane to the CVD chamber under a selective CVD condition; and
a second container holding the chlorine gas, the second container being operatively connected to supply the chlorine gas to the CVD chamber under the selective CVD condition.

32. The deposition system of claim 31, wherein the tetrachlorodisilane is 1,1,1,2-tetrachlorodisilane.

33. The deposition system of claim 31, wherein the trichlorodisilane is 1,1,1,-trichlorodisilane.

34. The deposition system of claim 31, wherein the chloropolysilane comprises at least two selected from monochlorodisilane, dichlorodisilane, trichlorodisilane, tetrachlorodisilane, pentachlorodisilane, hexachlorodisilane, chlorotrisilane, dichlorotrisilane, trichlorotrisilane, tetrachlorotrisilane, pentachlorotrisilane, hexachlorotrisilane, heptachlorotrisilane, and octachlorotrisilane.

35. The deposition system of claim 34, wherein the chloropolysilane comprises at least three selected from monochlorodisilane, dichlorodisilane, trichlorodisilane, tetrachlorodisilane, pentachlorodisilane, hexachlorodisilane, chlorotrisilane, dichlorotrisilane, trichlorotrisilane, tetrachlorotrisilane, pentachlorotrisilane, hexachlorotrisilane, heptachlorotrisilane, and octachlorotrisilane.

36. The deposition system of claim 34, wherein the chloropolysilane comprises dichlorodisilane and trichlorodisilane.

37. The deposition system of claim 36, wherein the dichlorodisilane and the trichlorodisilane are present in the chloropolysilane at a weight ratio in the range of about 1:9 to about 9:1.

38. The deposition system of claim 31, further comprising a carrier gas source operatively connected to the CVD chamber and configured to supply a non-hydrogen carrier gas to the CVD chamber.

39. The deposition system of claim 38 that is not configured to supply hydrogen gas to the CVD chamber.

40. The deposition system of claim 31 that is not configured to supply hydrogen chloride gas to the CVD chamber.

41. The deposition system of claim 31, wherein the CVD chamber is included in a horizontal flow, single wafer reactor.

42. The deposition system of claim 31, further comprising a computer operatively connected to the first container and the second container, and configured to control the flow of the chloropolysilane and the chlorine to the CVD chamber.

43. The deposition system of claim 42, further comprising a heater configured to heat the substrate, the computer being operatively connected to the heater and configured to control the temperature of the substrate.

44. The deposition system of claim 42, wherein the computer is configured to establish a selective CVD condition in the CVD chamber.
